(19) United States
(12) Patent Application Publication
(10) Pub. No.: US 2009/0178704 A1
(43) Pub. Date: Jul. 16, 2009

(54) Solar electric module with redirection of incident light

(76) Inventors: Juris P. Kalejs, Wellesley, MA (US); Michael J. Kardauskas, Billerica, MA (US); Bernhard P. Piwczyk, Dunbarton, NH (US)

Correspondence Address: J. SCOTT SOUTHWORTH ATTORNEY AT LAW, P.O. BOX 1287, FRAMINGHAM, MA, 01701, US

(21) Appl. No.: 12/012,588

(22) Filed: Feb. 4, 2008

Related U.S. Application Data
(60) Provisional application No. 60/888,337, filed on Feb. 6, 2007.
(60) Provisional application No. 60/931,440, filed on May 23, 2007.

(51) Int. Cl. H01L 31/052

(52) U.S. Cl. 136/246

(57) ABSTRACT

A solar electric module having a layered construction including a light redirection layer and light transmitting materials that encapsulate the solar cells of the module. The solar electric module provides for weight mitigation and/or moisture control features. The weight mitigation feature provides for the use of weight mitigation layers to reduce the volume of glass in a transparent top cover, while providing an increased distance between the light redirection layer and the transparent top cover. The increased distance supports increased spacing between solar cells. The moisture control feature provides perforations in a metallic coating layer and/or light redirection layer to support migration of moisture into and out of the encapsulating layers. The light redirection layer can be an asymmetric redirection layer (for example, light scattering layer) or a symmetric redirection layer (for example, a diffractive optical element).

### RELATED APPLICATION

This application claims the benefit of U.S. Provisional Patent Application No. 60/888,337, titled, “Solar Electric Module,” filed on Feb. 6, 2007, and claims the benefit of U.S. Provisional Patent Application No. 60/931,440, titled “Redirection of Light Incident on a Solar Cell Module,” filed on May 23, 2007; the entire teachings of which are incorporated herein by reference. This application is related to concurrently filed U.S. utility patent application, application Ser. No. ______, titled “Solar Electric Module,” by Juris P. Kalejs, Attorney Docket Number AMS-001, the entire contents of which are incorporated by reference.

### FIELD OF THE INVENTION

The invention relates to an improved solar cell module having reflector means designed to utilize light impinging on areas between the cells, which would normally not be utilized in photoelectric conversion, thereby increasing the power output of the cells.

### BACKGROUND

Photovoltaic cells have been long used as means of receiving solar energy and converting the solar energy into electrical energy. Such photovoltaic cells or solar cells are thin semiconductor wavers based on an EFG (edge-defined film-fed growth) substrate, which can be a polycrystalline silicon material. The solar cells can be various sizes and shapes. Several solar cells can be connected in series into a string by using electrical conductors. The strings of solar cells are arranged in a geometric pattern, such as in rows and columns, in a solar module and are interconnected electrically to provide an electric power output from the module. The solar module can contain features for reflecting or redirecting light within the module.

The light in a solar module can be redirected by any one of three optical phenomena: reflection, refraction and diffraction. Reflection can be illustrated with a simple mirror where incident light is reflected from a smooth surface at an angle normal to the surface such that the angle of incidence is equal to the angle of the reflected light but of opposite sign. Refraction can be illustrated by a ray of light in air entering another medium such as water or glass having a different refractive index compared to air. The angle of the refracted light is calculated using Snell's law:

n₁ sin θ₁=n₂ sin θ₂

where n is the refractive index of the medium and θ is the angle of incident light or refracted light.

A light reflector approach is used when the solar cells are spaced apart and a light reflecting material is placed in the spaces between the solar cells. Light is reflected upward from the light reflecting material, internally within the module, and some or all of the light may reach the front surface of a solar cell, where the solar cell can utilize the reflected light. U.S. Pat. No. 4,235,643 to Amick describes such an approach for solar cells that are typically circular or hexagonal in shape. The solar module includes a support structure which is formed from an electrically nonconductive material such as a high density, high strength plastic. Generally, support structures are rectangular in shape. Dimensions for a support structure are, in one example, 46 inches long by 15 inches wide by 2 inches deep. Arrayed on the top surface of the support structure are solar cells connected in series by means of flexible electrical interconnections. Thus, the electrode on the bottom of one solar cell is connected via a flexible end connector to the top bus bar of the next succeeding solar cell. The bus bars connect electrically conductive fingers on the front (top) surface of the cell. The support structure has circular wells on the surface for receiving circular solar cells, and the solar cells are interconnected in the desired fashion. The land areas (that is, the area between the individual solar cells) are provided with facets with light reflective surfaces for reflecting light which normally impinges on the land area at an angle such that the reflected radiation, when it reaches the front surface of the optical medium covering the solar cell array, is internally reflected back down to the front surface of the solar cell array. The array mounted on the support structure must be coupled with an optically transparent cover material. There should be no air spaces between the solar cells and the optical medium or between the land areas and the optical medium. Typically, the optically transparent cover material is placed directly onto the front surface of the solar cells. The optically transparent cover has an index of refraction generally between about 1.3 to about 3.0 and is in the range of about ⅛ inch up to about ⅜ inch thick.

In one design of conventional solar cell modules using a light reflector approach, the solar cells are rectangular or square in shape, spaced apart, and arranged in rows and columns. The solar cells are encapsulated or “packaged”, that is, bounded by physical barriers both on their front (top) and back (bottom) sides. Encapsulation helps to protect the solar cells from environmental degradation, such as from physical penetration and lessens degradation of the solar cells from the ultraviolet (UV) portion of the sun's radiation. Typically, the front barrier is a sheet of glass. The glass is bonded to a thermoplastic or thermosetting polymer encapsulant. This transparent or transmitting polymeric encapsulant is bonded to the front and back support sheets using a suitable heat or light treatment. The back support sheet may be in the form of a glass plate or a flexible polymeric sheet.

Another methodology for redirecting light uses a Lambertian light scattering surface. This methodology is essentially a white surface using finely dispersed particles, of Ti0₂ or Al₂0₃, for instance, to scatter light impinging on the surface. In the case of a solar electric module, having a front glass cover of a given thickness, any light scattered at an angle smaller than the critical angle, which in glass is about 42 degrees to a normal to the surface, is lost for conversion into electrical power because it exits the front glass surface, but any light scattered at a larger angle will be redirected toward an adjacent solar cell by total internal reflection.

When a radiator or reflector has a luminance independent of the viewing (or illuminating) angle, it is said to be perfectly diffuse. If it is plane, its apparent area, and therefore its intensity, will vary with cos θ, where θ is the angle between the normal to the surface and the direction of viewing. Such a reflector is said to obey Lambert's law:

I=I₀ cos θ

where (I) is the intensity of the light scattered at a given angle, and I₀ is the intensity of the incident light.

Lambert's law applies if the surface scatters light equally in all directions. Certain surfaces can be constructed that do not obey Lambert's law. This is the case for projection screens that are coated with small spheres of glass. Here a much larger proportion of light is reflected in the direction of the incident light than at greater viewing angles. Such a screen does not obey Lambert's law and can be referred to as Non-Lambertian. It is predictable that preferred scattering can occur if (i) particles of certain optical properties, due to the shapes, surface morphology and/or refractive index of the particles, can be incorporated in the surface, (ii) these particles by themselves have reflective properties that are directionally preferential and (iii) they can be oriented so that they tend to reflect or scatter light at angles greater than the critical angle of the transparent medium through which the light travels. That is to say, that, if these particles are embedded in a transparent polymer layer and if these particles have directionally preferential reflective properties, Lambert's law can be violated.

A detailed discussion of the physics involved in a scattering approach is given by L. Levi, Applied Optics, Vol. 1, P. 335-342, John Wiley & Sons, 1980, which is incorporated herein by reference.

Another methodology to produce preferred scattering employs a reflective surface that has preferential reflective properties. Such a surface can be generated by crystallizing certain chemicals or salts on a surface. The specific chemistry is based on the shape or form of the crystal that is formed so that the facets of the crystal tend to reflect light in an angle larger than a designated angle with respect to the normal to the surface. This is mainly a function of the crystal morphology of a given chemical or salt.

In addition, the orientation of the facets of a given crystal can be influenced by special seeding techniques. The surface formed by such crystallization can be used directly after over-coating with a thin light reflective coating or layer on the surface or the surface can be replicated by nickel plating and further replication in a polymer film with application of a reflective coating.

Another related methodology is the incorporation of small, even micron sized, bubbles in an optically clear polymer film. These bubbles can be made to depart from a spherical shape by the film extrusion process or other means, thus imparting optical properties in the film that do not conform to Lambert's law.

Yet another methodology is the incorporation of asymmetric or platelet type light reflecting particles into the polymer film. The reflecting properties of the particles can provide light redirection that does not conform to Lambert's law.

Another methodology for redirecting light uses a diffraction approach. The light redirection approach of diffraction is illustrated by light incident on a grating. The light is redirected by diffraction according to the equation

nλ=2d sin θ

where n is the order of diffraction, d is the periodicity or spacing of the grating and θ is the angle of diffraction. Diffraction and redirection of light in specific directions can be achieved by the use of specific diffraction gratings and holographic optical elements (HOEs) as illustrated by well-known holograms on credit cards and packaging materials. Yet another way of redirecting light, using diffraction, is the use of computer generated diffractive optical elements (DOEs).

The use of computer generated DOEs is described in “Digital Diffractive Optics—An Introduction to Planar Diffractive Optics and Related Technology,” B. Kress and P. Meyrueis, John Wiley & Sons, Ltd.,© 2000, the entire contents of which is incorporated herein by reference.

### SUMMARY OF THE INVENTION

In one aspect, the invention features a solar electric module including a transparent front cover; solar cells, a back cover, a light transmitting encapsulant, and a light redirection layer. The transparent front cover has a front surface and a back surface. The solar cells are configured in a substantially coplanar arrangement and spaced apart from each other. The back cover is spaced apart from and substantially parallel to the transparent front cover. The solar cells are disposed between the transparent front cover and the back cover. The solar cells have front surfaces facing the transparent front cover and back surfaces facing away from the transparent front cover, each solar cell having one front surface and one back surface. The light transmitting encapsulant is disposed between the transparent front cover and the back cover. The light redirection layer is disposed between the solar cells and the back cover. The transparent front cover transmits light through the transparent front cover. The light is incident on the light redirection layer in regions between the solar cells, the light redirection layer directing the light towards the transparent front cover. The front surface of the transparent front cover internally reflects the light back towards the front surfaces of the solar cells. The light redirection layer has a plurality of perforations of a predetermined size at least in regions obscured by the solar cells, the perforations providing moisture transport into and out from the light transmitting encapsulant.

In one embodiment, the light redirection layer is an asymmetric redirection layer providing light redirection in asymmetric directions. The asymmetric redirection layer, in another embodiment, includes a light scattering film and a light reflective layer. In one embodiment, only the light reflective layer includes the perforations. The perforations form, in a further embodiment, a plurality of windows. Each window is adjacent to each back surface of each solar cell. In another embodiment, the light scattering film and the light reflective layer have perforations or windows. Each perforation extends through the light scattering film and the light reflective layer.

In another embodiment, the light redirection layer is a symmetric redirection layer providing light redirection in symmetric modes. The symmetric redirection layer, in a further embodiment, includes a diffractive optical member. In one embodiment, the perforations form windows. Each window is adjacent to each back surface of each solar cell. The diffractive optical member, in another embodiment, includes a substrate, a surface having a diffractive relief pattern, and a metallic coating layer disposed onto the relief pattern surface. In a further embodiment, the substrate, the relief pattern surface, and the metallic coating layer have the perforations. Each perforation extends through the substrate, the relief pattern surface, and the metallic coating layer. The diffractive optical member, in another embodiment, further includes an insulation layer. In one embodiment, the substrate, the relief pattern surface the metallic coating layer, and the insulation layer have perforations. Each perforation extends through the substrate, the relief pattern surface, the metallic coating layer and the insulation layer. The relief pattern surface, in another embodiment, faces away from the back surface of the solar cells. The relief pattern surface, in a further embodiment, forms a one-level diffractive structure.

In another aspect, the solar electric module includes a transparent front cover; solar cells, a back cover, a light transmitting encapsulant, and a light redirection layer. The transparent front cover has a front surface and a back surface. The solar cells are configured in a substantially coplanar arrangement and spaced apart from each other. The back cover is spaced apart from and substantially parallel to the transparent front cover. The solar cells are disposed between the transparent front cover and the back cover. The solar cells have front surfaces facing the transparent front cover and back surfaces facing away from the transparent front cover. Each solar cell has one front surface and one back surface. A light transmitting layer is disposed between the transparent front cover and the back cover. The light transmitting layer encapsulates the solar cells. The light transmitting layer includes a first layer of transparent material disposed adjacent to the back surface of the transparent front cover and a second layer of transparent material disposed adjacent to the back surfaces of the solar cells. The light redirection layer is disposed between the solar cells and the back cover. The transparent front cover transmits light through the transparent front cover, and the light is incident on the light redirection layer in regions between the solar cells. The light redirection layer directs the light towards the transparent front cover. The front surface of the transparent front cover internally reflects the light back towards the front surfaces of the solar cells. The first layer of transparent material includes one or more encapsulating sheets adjacent to the front surfaces of the solar cells, and a weight mitigation layer disposed between the back surface of the transparent front cover and one or more encapsulating sheets. The weight mitigation layer has a density less than the transparent front cover, and replaces a volume of the transparent front cover equal to a volume of the weight mitigation layer.

In one embodiment, the light redirection layer is an asymmetric redirection layer providing light redirection in asymmetric directions. The asymmetric redirection layer, in another embodiment, includes a light scattering film and a light reflective layer. In a further embodiment, the light redirection layer is a symmetric redirection layer providing light redirection in symmetric modes. The symmetric redirection layer, in one embodiment, includes a diffractive optical member. In another embodiment, the diffractive optical member includes a substrate, a surface having a diffractive relief pattern, and a metallic coating layer. The diffractive optical member, in one embodiment, further includes an insulation layer. In another embodiment, the relief pattern surface faces away from the back surface of the solar cells. The relief pattern surface, in one embodiment, forms a one-level diffractive structure.

In one aspect, the invention features a solar electric module including a transparent front cover, solar cells, a back cover, a light transmitting encapsulant, and means for light redirection. The transparent front cover has a front surface and a back surface. The solar cells are configured in a substantially coplanar arrangement and spaced apart from each other. The back cover is spaced apart from and substantially parallel to the transparent front cover. The solar cells are disposed between the transparent front cover and the back cover. The solar cells have front surfaces facing the transparent front cover and back surfaces facing away from the transparent front cover, each solar cell having one front surface and one back surface. The light transmitting encapsulant is disposed between the transparent front cover and the back cover. The light redirection means is disposed between the solar cells and the back cover. The transparent front cover transmits light through the transparent front cover. The light is incident on the light redirection means in regions between the solar cells, the light redirection means directing the light towards the transparent front cover. The front surface of the transparent front cover internally reflects the light back towards the front surfaces of the solar cells. The light redirection means has perforations of a predetermined size at least in regions obscured by the solar cells. The perforations provide moisture transport into and out from the light transmitting encapsulant.

In one embodiment, the light redirection means is a means for asymmetric light redirection providing light redirection in asymmetric directions. In another embodiment, the light redirection means is a means for symmetric light redirection providing light redirection in symmetric modes.

In another aspect, the solar electric module includes a transparent front cover, solar cells, a back cover, a light transmitting encapsulant, and a light redirection means. The transparent front cover has a front surface and a back surface. The solar cells are configured in a substantially coplanar arrangement and spaced apart from each other. The back cover is spaced apart from and substantially parallel to the transparent front cover. The solar cells are disposed between the transparent front cover and the back cover. The solar cells have front surfaces facing the transparent front cover and back surfaces facing away from the transparent front cover. Each solar cell has one front surface and one back surface. A light transmitting layer is disposed between the transparent front cover and the back cover. The light transmitting layer encapsulates the solar cells. The light transmitting layer includes a first layer of transparent material disposed adjacent to the back surface of the transparent front cover and a second layer of transparent material disposed adjacent to the back surfaces of the solar cells. The light redirection means is disposed between the solar cells and the back cover. The transparent front cover transmits light through the transparent front cover, and the light is incident on the light redirection means in regions between the solar cells. The light redirection means directs the light towards the transparent front cover. The front surface of the transparent front cover internally reflects the light back towards the front surfaces of the solar cells. The first layer of transparent material includes one or more encapsulating sheets adjacent to the front surfaces of the solar cells, and a weight mitigation layer disposed between the back surface of the transparent front cover and one or more encapsulating sheets. The weight mitigation layer has a density less than the transparent front cover, and replaces a volume of the transparent front cover equal to a volume of the weight mitigation layer.

### BRIEF DESCRIPTION OF THE DRAWINGS

The above and further advantages of this invention may be better understood by referring to the following description in conjunction with the accompanying drawings, in which like numerals indicate like structural elements and features in various figures. The drawings are not necessarily to scale, emphasis instead being placed upon illustrating the principles of the invention.

FIG. 1 is a fragmentary diagrammatic side elevation illustrated solar cells arrayed on a support structure.

FIG. 2 is an exploded schematic representation of a cross section of a solar cell module including a weight mitigation layer in accordance with the principles of the invention.

FIG. 3 is a schematic representation of a cross section of a laminated solar cell module illustrating light reflection in accordance with the principles of the invention.

FIG. 4 is an exploded schematic representation of components of a solar cell module including a weight mitigation layer in accordance with the principles of the invention.

FIG. 5 is a schematic representation of a cross section of a laminated solar cell module including a weight mitigation layer in accordance with the principles of the invention.

FIG. 6 is a schematic representation of a cross section of components of a first transparent layer according to the principles of the invention.

FIG. 7 is an exploded schematic representation of a cross section of a solar cell module including a composite backskin in accordance with the principles of the invention.

FIG. 8 is a plan (overhead) view of a solar cell module including moisture permeability areas, according to the principles of the invention.

FIG. 9 is a schematic representation of a cross section of a laminated solar cell module including a moisture mitigation feature in accordance with the principles of the invention.

FIG. 10 is a plan (overhead) view of a solar electric module including a light scattering film according to the embodiment of the invention.

FIG. 11 is a schematic representation of a cross section of a solar electric module illustrating light redirection by a light scattering film, in accordance with the principles of the invention.

FIG. 12 is a schematic representation of a cross section of a solar electric module including a weight mitigation layer and moisture control perforations in a light scattering film, in accordance with the principles of the invention.

FIG. 13 is a schematic representation of a cross section of a solar electric module including a weight mitigation layer and moisture control windows in a light scattering film, in accordance with the principles of the invention.

FIG. 14 is a sectional view of a diffractive structure in accordance with the principles of the present invention.

FIG. 15A illustrates a phase template for a diffractive optical element comprising eight levels, according to the principles of the invention.

FIG. 15B illustrates a diffraction plane view for the pattern resulting from the incidence of a single square beam of light onto the diffractive structure of FIG. 15A.

FIGS. 16A-16D are sectional views taken along lines A-A, B-B, C-C, D-D, respectively, of FIG. 15A

FIG. 17A illustrates a phase template for a diffractive optical element comprising four levels, in accordance with the principles of the invention.

FIG. 17B illustrates a diffraction plane view for the pattern resulting from the incidence of a single square beam of light onto the diffractive structure of FIG. 17A.

FIGS. 18A-18D are sectional views taken along lines A-A, B-B, C-C, D-D, respectively, of FIG. 17A.

FIGS. 19A-19H illustrate steps for fabricating the structure of FIG. 17A.

FIG. 20 is a top plan view of a solar module having a diffractive optical member in accordance with the principles of the present invention.

FIG. 21 is a sectional view of the solar module of FIG. 20.

FIG. 22 is a sectional view of a solar module including a diffractive surface, in accordance with the principles of the invention.

FIG. 23 is a sectional view of a solar module including a weight mitigation layer and moisture control perforations in a diffractive optical member, in accordance with the principles of the invention.

FIG. 24 is a sectional view of a solar module including moisture control windows in a diffractive optical member, in accordance with the principles of the invention.

### DETAILED DESCRIPTION

This invention relates to the structure and manufacture of solar electric modules which include interconnected solar cells disposed between a front (top) protective support sheet or superstrate (which may be a flexible plastic sheet or a glass plate) transparent to most of the spectrum of the sun's radiation, and a back (bottom) support sheet or substrate. Elements and techniques for module construction are described which enable simpler manufacturing procedures and raise market acceptance of modules for large commercial flat roof installations, where the total weight of the modules may be excessive. These elements and techniques can be combined with concentrating light principles in module designs which use reflector materials to reduce module costs by reducing the number of solar cells used to as few as one-half to one-third of those used in conventional modules without a light reflector feature. In one aspect, the invention features a method to reduce the weight of a module while retaining cost benefits arising from a light reflecting material, thus increasing the market penetration window for the “low concentrator” general class of light reflector solar products. In another aspect, the invention features a method to simplify construction and manufacture of a module by combining at the back of the module the light reflection and cost reducing element with a conventional barrier sheet, which is termed the module “backskin.” In another aspect, the invention provides moisture control features, such as, in one embodiment, a backskin having a controlled moisture ingress to and egress from the module interior.

The approach of the invention simplifies module design and manufacture, and broadens the market for solar electric modules. Cost reductions are realized by enabling the total number of cells in a module to be reduced while maintaining module performance (that is, maintaining a similar level of output of electrical power as modules without the approach of the invention).

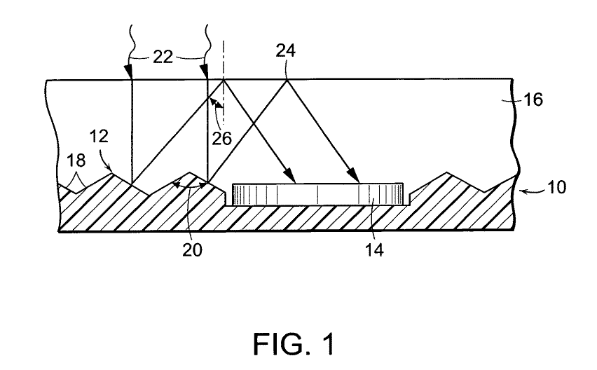

FIG. 1 is a fragmentary diagrammatic side elevation illustrated solar cells arrayed on a support structure. FIG. 1 illustrates one conventional approach for a light reflector module based on U.S. Pat. No. 4,235,643 to Amick. The approach shown in FIG. 1 is suitable for use with the approach of the invention, but is not limiting of the invention. Solar cells 14 are arrayed and mounted on a support structure 10 and then covered by and coupled with an optically transparent layer 16. The optically transparent cover material 16, as shown in the conventional approach of FIG. 1, for example, is any one of the silicone rubber encapsulating materials generally known to the electronics and solar cell industry or other ultra-violet stable and weather resistant materials.

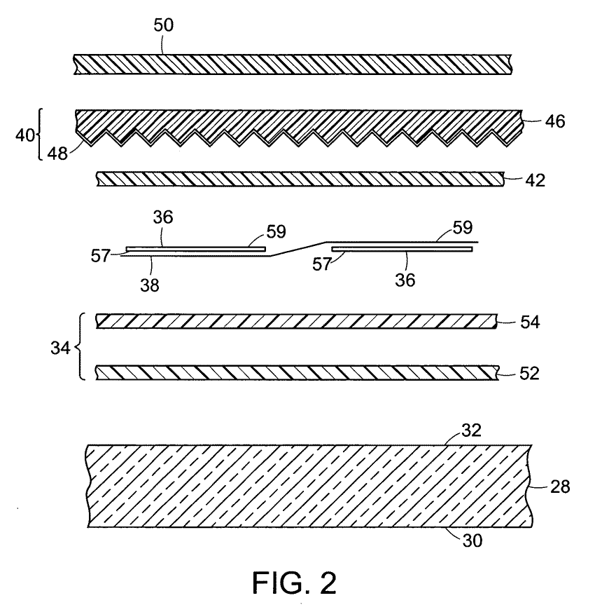

FIG. 1 is suitable for use with the approach of the invention in accomplishing a weight control or mitigation goal by replacing the optically transparent layer with a relatively thin sheet of glass forming a top layer, and an optically transparent plastic layer between the thin top sheet of glass and the solar cells 14. This approach of the invention combines the advantage of a hard, scratch resistance, protective cover of glass with the use of lighter weight, typically plastic, materials, as is discussed in more detail elsewhere herein (see FIGS. 2 through 6 illustrating the weight mitigation approach of the invention).

In the conventional approach of FIG. 1, the land areas 12 between the solar cells 14 arrayed on the surface of the support structure 10 have facets having light reflective surfaces 18. The light reflective surfaces 18 may be mirrored surfaces, polished metal and the like.

As is shown in the conventional approach of FIG. 1, the facets are in the form of V-shaped grooves having the light reflective surfaces 18. The depths of the grooves are generally in the range of about 0.001 inch to about 0.025 inch or approximately 0.1 of the thickness of the optically transparent cover material 16. The angle 20 at the vertex formed by two upwardly sloping planes of the facets or grooves must be in the range of about 110 degrees to 130 degrees and preferably at an angle of 120 degrees. Also, in one embodiment, the depth of the groove is about 0.3 millimeters.

As is shown in FIG. 1, the faceted region 12 is substantially coplanar with solar cells 14. In one embodiment, the vertical height of the facet will be equal to the thickness of a solar cell 14 and the facets will be arranged so that the facet will not extend below the bottom surface of the cell 14.

As can be seen in FIG. 1, normal vertically incident solar radiation designated, for example, generally by reference numeral 22, which impinges on normally inactive land areas 12 is reflected by the reflecting surfaces 18 of the facets provided in the land area 12 so that the radiation re-enters the optical medium 16. When the reflected radiation reaches the front surface 24 of the optical medium, and if it makes an angle 26 greater than the critical angle, the radiation will be totally trapped and reflected down to the back surface. The critical angle refers to the largest value which the angle of incidence 26 may have for a ray of light 22 passing from a more dense medium to a less dense medium. If the angle of incidence 26 exceeds the critical angle, the ray of light 22 does not enter the less dense medium but will be totally internally reflected back into the denser medium (the optical medium 16).

The solar radiation 22 on arrival can strike a solar cell 14 rather than the land region 12, in which event it will be absorbed and contribute to the electric output of the module. This ability to redirect light striking inactive surfaces so that it will fall on active surfaces permits arraying of the cells 14 at greater distances with minimum loss in output per unit area, hence raising the output power and/or lowering the cost per watt for a solar cell module.

Significantly, the geometry of the facets should be such that light reflected from surfaces 18 of the facets in land area 12 is not shadowed or blocked by an adjacent facet. Additionally, light upon being reflected from surfaces 18 and land area 12 when it reaches the front surface 24 of the optical medium 16 must make an angle 26 exceeding the critical angle with the front surface 24.

As indicated, the surfaces 18 of the grooves on land area 12 can be smooth optically reflecting surfaces; that is, they should have a solar absorptance less than 0.15. These surfaces can be prepared by coating machined or molded grooves with a suitable metal such as aluminum or silver, for example.

By way of example but not limitation on the approach of the invention, solar cell modules may take the form described and illustrated in U.S. Pat. Nos. 5,478,402 to Hanoka, 6,586,271 to Hanoka and 6,660,930 to Gonsiorawski, the entire contents of which are incorporated herein by reference. Generally, these patents (U.S. Pat. Nos. 5,478,402; 6,586,271; and 6,660,930) describe solar cell modules composed of layered constructs typically including a transparent front cover, a plastic (encapsulating) layer, solar cells 14, a plastic (encapsulating) layer, and a back cover. The solar cells 14 are typically connected by electrical conductors that provide electrical connections from the bottom surface of one solar cell 14 to the top surface of the next adjacent solar cell 14. The solar cells are connected in series into a string of solar cells 14.

In some conventional approaches, a reflecting layer is included behind the array of solar cells 14. Such a reflecting layer has been proposed in various embodiments of module construction. By way of example but not limitation on the approach of the invention, solar cell modules may take the form described in U.S. Pat. No. 5,994,641 to Kardauskas (hereinafter “Kardauskas”), which is also known as a “low concentrator” module design. The disclosure of Kardauskas is incorporated herein by reference. Generally, Kardauskas describes a solar cell module having a transparent front cover, a plastic layer, solar cells 14, a reflecting layer, a plastic layer, and a back cover.

FIG. 2 is an exploded schematic representation of a cross section of a solar cell module including a weight mitigation layer 52 in accordance with the principles of the invention.

The disclosed module construction shown in FIG. 2 includes a transparent front panel (for example, front sheet of glass) 28, a first layer of encapsulant 34, which is placed in front of the solar cells designated generally by the reference numeral 36 and in which the solar cells 36 are embedded, a second (back) layer of encapsulant 42, a reflecting layer 40, and a sheet of “back” glass 50. The reflecting layer 40 includes a reflecting layer support 46, which is preferably a polymer sheet coated with a thin metal layer 48. The reflector layer support 46 is bonded to the back glass 50.

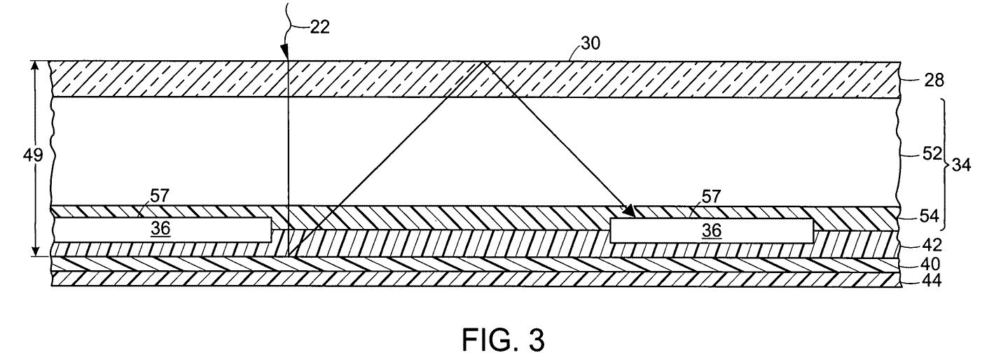

The transparent front panel 28 has a front surface 30 and back surface 32. The transparent front panel 28 is composed of one or more transparent materials that allow the transmission of solar light rays 22 (shown in FIG. 3). In one embodiment, the transparent front panel 28 is glass, having a density of about 2 to 4 grams per cubic centimeter. In other embodiments, the transparent front panel 28 is composed of a transparent polymer material, such as an acrylic material.

The solar cells 36 have a front surface 57 and a back surface 59. The solar cells 36 are connected by conductors designated generally by the reference numeral 38 (also referred to as “tabbing”).

The reflecting layer 40 with reflective coating 48 provides a reflecting layer for one embodiment of the invention. The reflective coating 48 is a metallic material, for example aluminum. In another embodiment, the reflective coating 48 is silver, which is more reflective than aluminum but is typically also more expensive. In one embodiment, the reflective coating 48 is coated or overlaid with a transparent electrically insulating layer to prevent electrical current from flowing between the reflective coating 48 and any conductors 38 or electrical contacts associated with the back surfaces 59 of the solar cells 36, or other electric circuitry associated with the module In preferred embodiment the reflective coating or layer 48 is located on a surface of the support 46 that is facing the backskin 44 or back panel 50. The support 46 is transparent to light so that light rays 22 can pass through the support, are incident on the reflecting coating or layer 48, and reflected back through the support 46 toward the transparent front panel 28.

By way of example but not limitation on the approach of the invention, the approach of the invention is also suitable for use with a grooved reflective support layer 46 according to the approach of Amick. The depths of the grooves are generally in the range of about 0.001″ to 0.025″ or approximately 0.1 of the thickness of the optically transparent cover material. The angle 20 (see FIG. 1) at the vertex formed by two upwardly sloping planes of the facets or grooves must be in the range of about 110 degrees to 130 degrees and preferably at an angle of 120 degrees.

By way of example but not limitation on the approach of the invention, the approach of the invention is suitable for use with a grooved reflective support layer 46 according to the approach of Kardauskas. One example provided in Kardauskas indicates that the support layer 46 has a thickness of about 0.004 inch to about 0.010 inch and V-shaped grooves. The grooves have an included angle between 110 degrees and 130 degrees (as in angle 20 in FIG. 1). In one embodiment, the grooves have a depth of above 0.002 inch, and a repeat (peak to peak) spacing of about 0.007 inch. The reflective coating 48 of aluminum or silver has a thickness in the range of about 300 angstroms to about 1000 angstroms, preferably in the range of 300 angstroms to about 500 angstroms. The facets, in one embodiment, are in the form of V-shaped grooves.

The first layer of encapsulant 34 includes one or more weight control sheets or layers designated generally by the reference numeral 52 and encapsulating sheet 54 (to be discussed in more detail elsewhere herein.

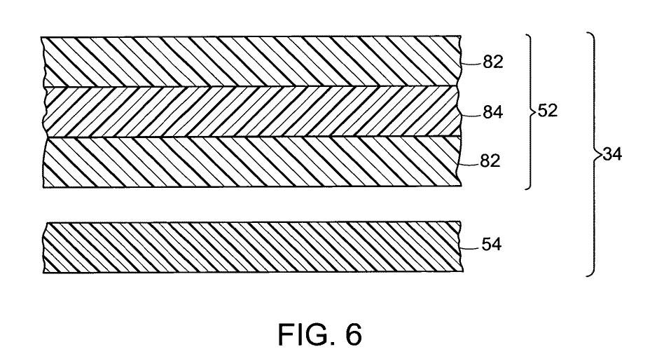

Generally, the encapsulating layers 34 and 42 include one or more plastic materials. In one embodiment, the layers 34 and 42 include ethyl vinyl acetate (EVA). The layers 34 and/or 42 can include other materials, such as UV blocking materials which aid in preventing degradation of the EVA, or the UV blocking materials can be included in the EVA. In another embodiment, the encapsulating layers 34 and 42 include an ionomer. In further embodiments, the encapsulating layer 34 includes both EVA and ionomer materials (see FIG. 6). In various embodiments, the encapsulating layers 34 and 42 are composed of a UV-resistant EVA material, such as 15420/UF or 15295/UF provided by STR (Specialized Technology Resources, Inc.) that resists degradation and yellowing.

In one aspect of the invention, a weight mitigation approach is featured. One related problem is the lack of availability of material used to construct solar cells. Efficient modules having reduced numbers of solar cells 36 have become increasingly desirable in recent years due to shortages of silicon raw material, or “feedstock.” Silicon solar cell based products comprise over 85% of the current solar electric products sold worldwide in 2006.

One aspect of the invention features a solar electric module (see FIG. 2) having a reduced weight compared to existing solar electric modules. The reduced-weight module with fewer numbers of silicon solar cells 36 is advantageous for large-area flat roof installations. The amount of silicon feedstock required for each watt of module power and kWh of energy produced over the module lifetime is reduced. In many implementations of flat roof arrays of solar cells 36, the arrays include between 3000 and 5000 solar electric modules. Each module typically weighs approximately 50 lbs. Typically, the modules are installed on warehouses with large roof areas. Racks of modules are sufficiently heavy that typically they are hoisted to the roof with tall cranes for installation. Installed weight is a critical factor in flat roof array applications. The problem of excessive installed weight (for example, more than five pounds per square foot) prevents acceptance of module products if the weight is more than the acceptable threshold. Module weight often comprises 50 to 75% of the installed array roof load. It is often desirable to reduce the installed weight to the five pounds per square foot threshold or lower. Total roof loads for large module arrays without any weight reduction or mitigation features typically range from 50 to 100 tons.

For example, a front cover glass sheet of 3 mm thickness allows solar cells 36 to be spaced by greater distances than solar cells 36 in prior (conventional) solar electric modules, resulting in a reduction of the number of solar cells 36 by one third while maintaining parity to within about 10 percent to about 15 percent in module power density for a given area. The cell spacing can be further increased and the number of solar cells 36 can further be reduced by an additional about 30 percent to about 50 percent if the thickness of the front glass cover sheet 28 is doubled to 6 millimeter from 3 millimeter. The reduction in solar cells 36 is approximately one-half to one-third of the cells 36 (compared to the number of solar cells 36 used in a conventional module without the reflecting layer 40). Doubling the glass thickness (for example to 6 mm) can increase the installed weight density to seven to eight pounds per square foot. The increased weight can make the module unsuitable for a large number of flat roof installations despite the reduced number of solar cells 36.

According to embodiments of the invention, one or more extra sheets 52 of transparent material (that is, the encapsulant) are inserted between an encapsulating layer 54 of typical thickness (that is, in a range of about one-half millimeter to about one millimeter) and the front cover glass 28 The extra weight mitigation sheets 52 increase the separation between the solar cells 36 and the air-glass interface (the front surface 30 of the transparent front panel 28) at which total internal reflection occurs. Using additional encapsulant layers 52 instead of increasing glass thickness achieves the desired reduction in the number of solar cells 36 with less increase in weight than would otherwise occur for the increased glass thickness. In various embodiments, the extra sheets of weight mitigation material 52 can be thermosetting plastic ethyl vinyl acetate (EVA), ionomer, or a combination of sheets of EVA and ionomer. In other embodiments, additional encapsulant layers 36 can be used in combination with an increased glass thickness. The weight mitigation material 52 has a density less than the density of a glass transparent front panel 28, which in one embodiment has a density in a range of about 2 grams per cubic centimeter to about 4 grams per cubic centimeter.

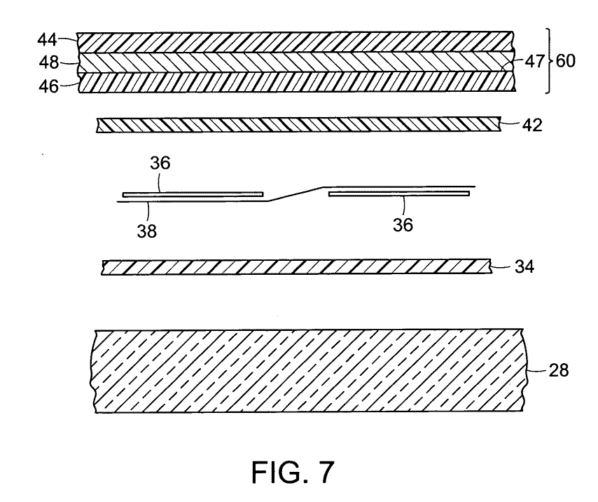

FIG. 3 is a schematic representation of a cross section of a laminated solar cell module illustrating a light reflection in accordance with the principles of the invention. The laminated solar cell module of FIG. 3 includes a transparent front panel 28, first light transmitting layer 34, solar cells 36, second light transmitting layer 42, reflecting layer 40 including reflective coating 48 (not shown), and backskin 44. The first light transmitting layer 34 includes weight mitigation layer 52 and encapsulating sheet 54. The weight mitigation layer 52, in one embodiment, includes multiple encapsulating sheets (not shown in FIG. 3, see FIG. 6). Incident light 22 is transmitted through the front transparent panel 28, is reflected upwards by the reflecting layer 40, reflected internally by the top surface 30 of the transparent front panel 28, and then impinges on the top surface 57 of a solar cell 36. The reflecting layer distance 49 (also termed light redirecting layer distance 49) is the distance between the reflecting layer 40 and the front surface 30 of the transparent front panel 28. The dimensions of the illustrated components 28, 52, 54, 36, 42, 40, and 44 are not necessarily to scale in FIG. 3. The reflecting layer 40 includes a reflective coating support 46 with a metallic coating 48. In other embodiments, the reflecting layer 40 is a metallic layer (for example, aluminum or silver). In another embodiment, the reflecting layer 40 is a composite backskin 60 (see FIG. 7).

In the approach of the invention, the goal is to increase the reflecting layer distance 49 without increasing the weight of the transparent front panel 28 (for example, when the transparent front panel 28 is glass). When the reflecting layer distance 49 is increased, the incident radiation 22 can be reflected a greater horizontal distance, because the incident radiation 22 is reflected upward at an angle and then reflected by the front surface 30 downward at an angle, which allows the solar cells 36 to be spaced farther apart with the increase in the reflecting layer distance 49 provided by the weight mitigation layers 52.

In one typical conventional approach, which is not meant to be limiting of the invention, the transparent front panel 28 is a glass sheet of about three millimeters in thickness, the encapsulating sheet 54 has a thickness of about 0.5 millimeters, (no weight mitigation sheet 52 is included), the solar cell 36 has a thickness of about 0.25 millimeters or less, the reflecting layer 46 is 0.25 millimeters (or less), the second or back encapsulating sheet 42 is about 0.25 millimeters, and the back cover is about 0.25 millimeter.

In the approach of the invention, the first layer of light transmitting material 34 includes both the encapsulating sheet 54 and one or more weight mitigation sheets 52. The one or more sheets of the weight mitigation layer 52 can form a layer as thick as 10 millimeters, in one embodiment, while the solar electric module retains a relatively thin thickness for the transparent front panel 28. The increased weight mitigation thickness increases the reflecting layer distance 49, which in turn, allows a greater spacing between the solar cells 36.

In one conventional approach, the solar electrical module includes a transparent front cover 28 of glass which is about ⅛ inch in thickness and the solar cells 36 are about 10 mm apart in spacing.

In the approach of the invention, the weight mitigation layer 52 is included, so that the transparent front cover 28 is about ⅛ inch or about 5/32 inch in thickness (or about 3 millimeters or less in thickness) and the spacing between solar cells can be increased to a range of about 15 to about 30 millimeters. In various embodiments, the width of the solar cells 36 are in the range of about 25 to about 75 millimeters. In one embodiment, the solar cells 36 have a thickness of about 0.25 millimeters (or less) and are rectangular in shape with the long dimension being about 125 millimeters, and the short dimension being about 62.5 millimeters. In various embodiments of the invention, the transparent front panel 28 ranges in thickness from one millimeter to ten millimeters in thickness. In preferred embodiments of the invention, the transparent front panel 28 ranges in thickness from about ⅛ inch to about ¼ of an inch in thickness. In other preferred embodiments the transparent front panel 28 ranges in thickness from about 3 millimeters to about 6 millimeters in thickness.

In one preferred embodiment of the invention, the reflecting layer 40 provides a light recovery of about 20 to about 30 percent. The transparent front cover 28 is about 3 millimeters in thickness, and the weight mitigation layer 52 is about 3 millimeters. The solar cells 36 have dimensions of about 62.5 millimeters by about 125 millimeters and a thickness of about 0.25 millimeters or less. The solar cells 36 have a spacing of about 15 millimeters apart.

In other embodiments, the solar cells 36 have the form of strips (also termed “ribbons”) with a width of about 8 millimeters to about 25 millimeters and a length in the range of about 100 millimeters to about 250 millimeters.

In another embodiment, the strip solar cell 36 is about 25 millimeters wide by about 250 millimeters in length. The spacing between the strip solar cells 36 is about 5 millimeters to about 25 millimeters. The weight mitigation layer 52 has a thickness of about 3 millimeters to about 6 millimeters (and up to 10 millimeters). In one embodiment, the solar electric module has about 60 strip solar cells 36 of about 25 millimeters in width and 250 millimeters in length, each strip solar cell 36 producing about 0.6 volts, so that the open circuit voltage output of the solar electric module is 36 volts.

In various embodiments of the invention, the weight mitigation layer 52 ranges in thickness from about one-half millimeter to about 10 millimeters. In one embodiment, the transparent front panel 28 has a thickness of about 3 millimeters to about 6 millimeters and the weight mitigation layer 52 has a thickness of about 2 millimeters to about 6 millimeters. The weight mitigation layer 52, in another embodiment, includes six sheets of EVA, each sheet having a thickness of about one-half millimeter. In another embodiment, the transparent front panel 28 has a thickness of about 2 millimeters and the weight mitigation layer 52 has a thickness of about 5 millimeters.

The weight mitigation aspect of the invention retains the advantages of a glass cover 28 (for transparency, resistance to degradation, protection of the front of the module, moisture impermeability that does not transmit water, and hardness (scratch resistance)) while limiting the thickness (and weight) of the transparent front panel 28. The use of the weight mitigation layer 52 increases the reflecting layer distance 49, which, in turn allows the solar cells 36 to be space farther apart. As a result, a solar electric module can provide about the same power output with fewer solar cells 36 compared to a solar electric module without any weight mitigation layer 52.

Generally, the weight mitigation aspect of the invention also provides the unexpected result of increased reliability, because there are fewer solar cells 36. The weight mitigation approach of the invention also provides the unplanned and fruitful result of providing more U-V protection to components (for example, reflecting layer 40) below the weight mitigation layer 52, because the increased polymer layer (for example, EVA) typically has U-V blocking or absorbing properties.

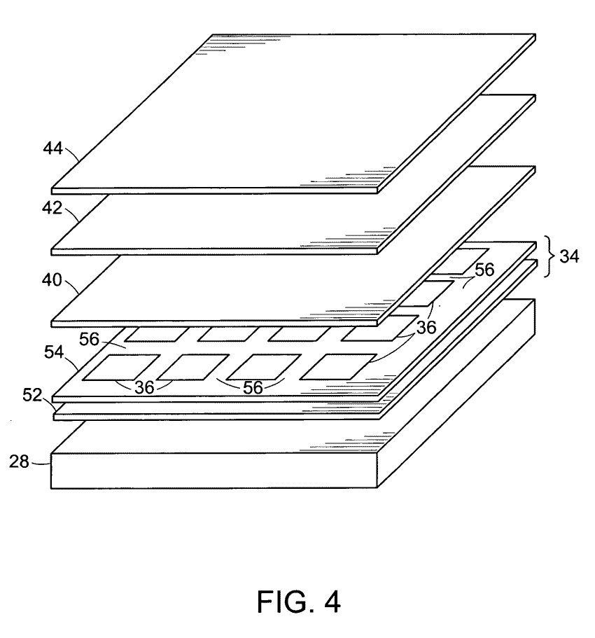

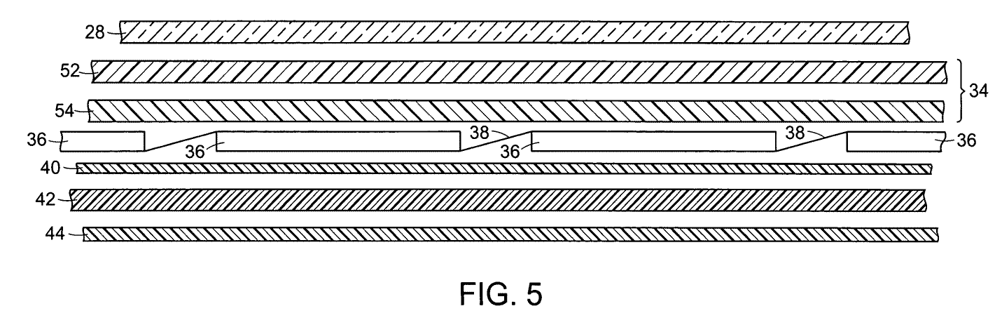

FIG. 4 is an exploded schematic representation of components of a solar cell module including a weight mitigation layer 52 in accordance with the principles of the invention. FIG. 5 is a schematic representation of a cross section of a laminated solar cell module including a weight mitigation layer 52 in accordance with the principles of the invention. The solar cell module illustrated in FIGS. 4 and 5 includes a superstrate or transparent front panel 28, a first layer of light transmitting material 34, an array of separately formed crystalline solar cells 36, regions between solar cells designated generally by reference numeral 56 (shown in FIG. 4), reflecting layer sheet 40, second layer of transparent encapsulant 42, and 44 backskin. The first layer 34 includes a weight mitigation layer 52 and an encapsulating sheet 54. FIG. 5 illustrates the conductors 38 (for example, tabbing) that electrically interconnect the solar cells 36. In one embodiment, the reflecting layer sheet 40 includes the grooved technology illustrated in FIG. 2 as reflective coating support 46 and reflective coating 48. In other embodiments, the reflecting layer 40 is based on other approaches without requiring the grooved approach shown for the reflective coating support 46 in FIG. 2. In another approach, the reflecting layer 40 includes a mirrored, polished metal, and/or patterned surface (having patterns other than grooves) that is reflective or is coated with a metallic reflective material 48. These reflective materials include aluminum, silver, or other reflective material. In one embodiment, the reflecting layer 40 is a white surface based on any suitable material, or other suitable reflecting layer or structure, as well as reflecting layers to be developed in the future. In one embodiment, the reflecting layer 40 is positioned between the second light transmitting layer 42, which is adjacent to the solar cells 36, and the backskin 44. Generally the approach of the invention does not require that the layers be provided in the order shown in FIG. 4 and FIG. 5.

The solar electric module of the invention can be fabricated using lamination techniques. In this approach, separate layers of the invention, 28, 34, 36, 40, 42, and 44 can be assembled in a layered or stacked manner as shown in FIGS. 4 and 5. The layers can then be subjected to heat and pressure in a laminating press or machine. The first light transmitting layer 34 and the second layer 42 are made of plastics (e.g., polymer, EVA, and/or ionomer) that soften or melt in the process, which aids in bonding all of the layers, 28, 34, 36, 40, 42, and 44 together.

By way of example but not limitation on the approach of the invention, the solar electric module of the invention can be fabricated using a lamination technique such as that disclosed in U.S. Pat. No. 6,660,930 to Gonsiorawski. Referring to FIG. 4 and FIG. 5, components of a conventional form of solar cell module are modified to incorporate the present invention and its manufacturing steps are shown. The dimensions of the illustrated components are not necessarily to scale in FIG. 4 and FIG. 5.

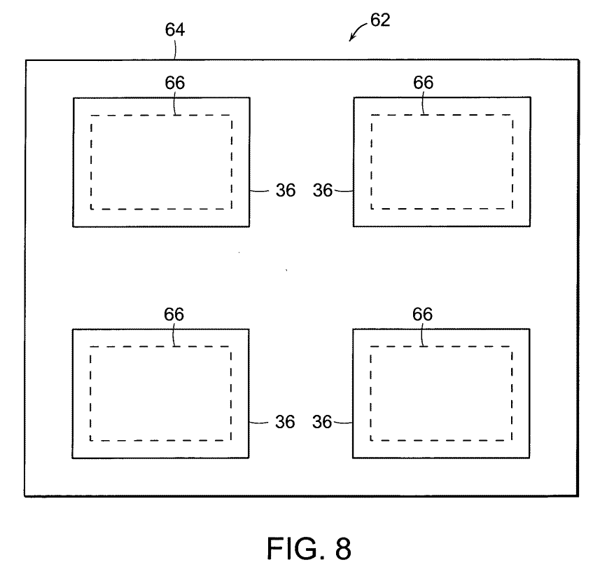

In the approach of the invention, reflecting layer sheet 40 is inserted separately as shown in FIG. 5 or it is formed as a composite 60 (see FIG. 7) with the backskin 44. The backskin can have perforations adjacent to the back side of the solar cells 36 in order to admit passage of a controlled amount of moisture according to one aspect of the invention (see FIGS. 8 and 9).

In this conventional manufacturing process, although not shown in FIG. 4 or FIG. 5, it is to be understood that some, and preferably all, of the individual conductors 38 that connect adjacent solar cells or strings of cells are oversize in length for stress relief and may form individual loops between the cells. Each cell has a first electrode or contact (not shown) on its front radiation-receiving surface 57 and a second electrode or contact (also not shown) on its back surface 59, with the conductors 38 being soldered to those contacts to establish the desired electrical circuit configuration.

In the approach of the invention, each of the layers 34 and 42 include one or more sheets of encapsulant material, depending upon the thickness in which the encapsulant is commercially available, or the thickness required to replace glass by encapsulant (as indicated by inclusion of a weight mitigation layer 52 as described for FIG. 2) in order to reduce module weight.

Although not shown, it is to be understood that the solar cells 36 are oriented so that their front contacts face the glass panel 28, and also the cells 36 are arranged in rows; that is, strings, with the several strings being connected by other conductors (not shown) similar to conductors 38 and with the whole array having terminal leads (not shown) that extend out through a side of the assembly of components. In one embodiment of the invention, electrically insulating film or materials are placed over the contacts on the solar cells 36 (before the assembly and lamination process) to prevent an electrical current flowing between the contacts and the reflecting layer 40, or other parts of the module.

The foregoing components 28, 34, 36, 40, 42, 44, are assembled during manufacturing in a laminate configuration starting with the glass panel 28 on the bottom. After the laminate is assembled into a sandwich or layered construct of components 28, 34, 36, 40, 42, and 44, the assembly is transferred to a laminating apparatus (not shown) where the components 28, 34, 36, 40, 42, and 44 are subjected to the laminating process. The laminating apparatus is essentially a vacuum press having heating means and a flexible wall or bladder member that contacts with a wall member or platen to compress the components 28, 34, 36, 40, 42, and 44 together when the press is closed and evacuated. The sandwich, or layered construct of components 28, 34, 36, 40, 42, and 44 shown in FIGS. 4 and 5, is positioned within the press and then the closed press is operated so as to heat the sandwich (or layered construct) in vacuum to a selected temperature at which the encapsulant melts enough to flow around the cells 36, usually at a temperature of at least 120 degrees C., with the pressure applied to the components 28, 34, 36, 40, 42, and 44 increasing at a selected or predetermined rate to a maximum level, usually about one atmosphere. In various embodiments, the temperature is as high as 150 degrees C. These temperature and pressure conditions are maintained long enough, typically for about 3 to 10 minutes, to allow the encapsulant of layer 54 to fill in all spaces around the cells 36 and fully encapsulate the interconnected cells 36 and fully contact the front and back panels 28 and 44, after which the pressure is maintained at or near the foregoing minimum level while the assembly (the layered construct) is allowed to cool to about 80° C. or less so as to cause the encapsulant of layers 34 and 42 to form a solid bond with the adjacent components 28, 36, 38, 40, and 44 of the module. The pressure exerted on the sandwich (layered construct) of module components 28, 34, 36, 38, 40, 42, 44 reaches its maximum level only after the assembled components 28, 34, 36, 38, 40, 42, 44 have reached the desired maximum temperature in order to allow the encapsulant of layers 34, 42 to reform as required and also to assure full removal of air and moisture. The module is completed by attaching to the laminate sandwich (that is, laminated layered construct) a junction box with wiring to external connectors and a frame (for example, a rectangular frame that surrounds and holds a rectangular laminated layered construct and that connects to a rack that supports multiple modules).

The manufacturing process, as described for FIG. 4 and FIG. 5, is not limiting of the invention but can be applied to solar electric modules having layered constructs as shown in other figures elsewhere herein (see FIG. 2, 3, 6, 7 or 9), including layered constructs that have different layers or layers in a different order than is shown in FIGS. 4 and 5. In one embodiment, the second light transmitting layer 42 of encapsulant is placed next to the solar cells 36; as a result, during the lamination process, the solar cells 36 are encapsulated by the encapsulating sheet 54 (part of the first light transmitting layer 34) and by the encapsulating material of the second layer 42 (see for example FIG. 3). The manufacturing process, as described for FIGS. 4 and 5, is not limiting of the invention and can also be applied to solar electric modules having different electrical conductors between solar cells 36 than the tabbing 38 indicated in FIG. 5.

FIG. 6 is a schematic representation of a cross section of components 52, 54, 82 and 84 of a first transparent layer 34 according to the principles of the invention. The first transparent layer 34 includes the weight mitigation layer 52 and the encapsulating sheet 54. In various embodiments, the weight mitigation layer 52 includes one or more plastic sheets of polymer, ionomer, or both. In one embodiment, the weight mitigation layer 52 includes EVA layers designed generally by reference numeral 82 and one or more ionomer layers designated generally by reference numeral 84 (shown as one ionomer layer 84 in FIG. 6). The ionomer layer 84 has the advantage of providing heightened protection from UV rays than would be otherwise provided if only having EVA layers, because the ionomer material provides UV blocking properties. Thus, the inclusion of an ionomer layer 84 provides additional protection against UV-caused degradation that can occur in the EVA layers (for example, 82 and 54) that have the ionomer layer 84 between them and the light source (sun). Thus the use of an ionomer layer 84 provides the unexpected and fruitful result of also providing additional U-V protection.

In the embodiment shown in FIG. 6, one ionomer layer 84 is shown sandwiched (or intermediate) between two EVA layers 82. Thus a layered construct for the weight mitigation layer 52 is formed that includes one or more EVA layers 82, then one or more ionomer layers 84, and then one or more EVA layers 82. In various embodiments, the weight mitigation layered construct of ionomer and EVA layers is not limited by the invention to what is shown in FIG. 6, and other layered constructs can be used. For example, the layers can be one or more EVA layers 82, one or more ionomer layers 84, one or more EVA layers 82, one or more ionomer layers 84, and one or more EVA layers 82.

The EVA layers 82 and the ionomer layer 84 are bonded together by the lamination process. In other embodiments, the layers 82 and 84 are bonded together by various processes such as an adhesive approach or other suitable process.

In another embodiment, the weight mitigation layer 52 includes an ionomer layer 84 having 2 sheets of ionomer and 2 sheets of EVA 82, each sheet of ionomer having a thickness of about one millimeter, and each sheet of EVA 82 having a thickness of about one-half millimeter. The ionomer layer 84 (including two sheets of ionomer) is bonded between the two sheets of EVA 82.

In one embodiment, the weight mitigation layer 52 includes a sheet of ionomer 84 having a thickness of about one millimeter, and two sheets of EVA 82, each sheet of EVA having a thickness of about one-half millimeter. The sheet of ionomer 84 is bonded between the two sheets of EVA 82.

FIG. 7 is an exploded schematic representation of a cross section of a solar cell module including a composite backskin 60 in accordance with the principles of the invention. The composite backskin 60 is formed from a backskin 44 that is contoured (for example with V-shaped grooves or another pattern) and coated with a reflective coating 48. The approach of the invention shown in FIG. 7 provides a simplified module construction in which the reflector material (for example, reflective coating 48) and backskin 44 form a single sheet of material. In one embodiment, the backskin 44 is formed from a polymer material imprinted with a pattern. In one embodiment, the pattern includes grooves (for example V-shaped grooves) or pyramids of predetermined dimensions. In one embodiment, the composite backskin 60 includes a substrate or support 46 with the reflective coating 48 disposed on a back surface 47 of the support 46 facing the backskin 44. The support 46, reflective coating 48, and backskin 44 are bonded together to form the composite backskin 60.

In an alternate embodiment, the backskin material 44 or support 46 can have an embedded light reflecting pattern produced by predetermined variations in refractive index. In such an approach the composite backskin 60 provides a diffractive or holographic pattern that causes incident light to be diffracted upwards toward the transparent front panel 28 where the diffracted light is reflected back by the front surface 30 toward the upper surfaces 57 of the solar cells 36. In a composite backskin 60 which includes a reflector material (for example reflective coating 48), the manufacturing steps and robotic equipment required can be reduced to simplify manufacturing procedures and lower production costs. In one embodiment, the assembly process for a laminated solar electric module (for example as shown in FIG. 5), requires fewer layers to assemble, because the two layers (reflective coating 48 and backskin 44) or three layers (substrate or support 46 with reflective coating 48 on a back facing surface of 46, and backskin 44) are combined into one layer for the composite backskin 60 and received at the module assembly facility or factory as one sheet of material.

In one embodiment, the approach of the invention is used with a composite backskin 60 according to U.S. Published Patent Application US 2004/0123895 to Kardauskas and Piwczyk, the contents of which are incorporated herein by reference.

According to another aspect of the invention, the reflecting sheet or layer 40 and/or backskin composite 60 including the reflective coating 48 are fabricated to allow various degrees of moisture (that is, water) penetration. FIG. 8 is an plan (overhead) view of a solar cell module 62 including moisture permeability areas 66, according to the principles of the invention. In the overhead view shown in FIG. 8, the moisture permeability areas 66 are areas underneath the solar cells 36. In one embodiment, the moisture permeability areas 66 are windows (for example, openings or apertures) in the moisture control reflector layer 64 that are the same size as the moisture permeability areas 66 or are a smaller size. In one embodiment, each window is less than the area of the solar cell 36. In another embodiment, each window is about 90 percent of the area of the solar cell 36. In other embodiments, the moisture permeability areas 66 include one or more windows that are smaller in size than the moisture permeability areas 66 shown in FIG. 8. In one embodiment, the moisture control reflector layer 64 is a reflecting layer 40 that includes moisture control features, as shown in and discussed for FIG. 8 and FIG. 9. FIG. 9 is a schematic representation of a cross section of a laminated solar cell module including a moisture mitigation feature in accordance with the principles of the invention. The solar cell module of FIG. 9 shows a reflecting layer 40 that is a metallic layer or includes a metallic layer 48 that is impervious to the migration of moisture. The reflecting layer 40 has perforations designated generally by the reference numeral 70. The perforations 70 allow for the travel of moisture that accumulates in the encapsulant volume 68, which, in one embodiment, includes EVA. In one embodiment, the encapsulant volume 68 includes the first light transmitting layer 34 and the second light transmitting layer 42. If the permeability is too high, then corrosion may occur within the solar module because there is too much moisture; and if the permeability is too low, then corrosion may occur because acetic acid, moisture, and other corrosive molecules cannot migrate out of the module.

To achieve the desired penetration, reflector metal films used in the reflector layer 40 (or composite backskin 60) are generated with a moisture permeability area 66 or perforations 70 to increase moisture transport adjacent to the back of each solar cell 36 as required by the encapsulant properties. In one embodiment, the moisture permeability area 66 includes perforations 70 in the reflector layer 40 (or composite backskin 60).

Small molecules (such as acetic acid, water, and/or other corrosive molecules) designated generally by the reference numeral 72 can migrate into or out of the encapsulant volume 68 are, shown in FIG. 9. A small molecule 72A located in the encapsulant volume 68, migrates on a sample path 74, through a perforation 70 to a location for the molecule 72B outside of the solar electric module. The small molecule 72B is the same molecule as 72A after following the sample path 74 from the location of molecule 72A to the location indicated by 72B. The encapsulant volume 68 is an encapsulating material (for example, polymer) that allows moisture related molecules to migrate throughout the encapsulant volume 68. The backskin 44 is a moisture permeable material that also allows moisture migration. The reflecting layer 40 is resistant or impervious to moisture migration. The reflecting layer 40 and/or the metallic reflective coating 48 include perforations 70 (or windows) to allow moisture migration. If the reflecting layer 40 has a layer or coating of an electrically insulating material, then the insulating material is typically also impervious or resistant to moisture and also has perforations 70 to allow moisture migration.

In one embodiment, the moisture control feature of the invention is used with conventional reflector metal films such as those described in Kardauskas.

By example, module design and materials are selected depending on their water retention index, moisture permeability and the susceptibility of the materials interior to the module to produce byproducts through the action of UV radiation and temperature excursions, which then may subsequently combine with water to degrade module properties. Water vapor also affects the integrity of the bond between various sheet materials in a module (for example, layers 34, 40, 42 and 44) and the strength of the interface bonding to glass (for example, bonding of the first transparent layer 34 to a glass transparent front panel 28). The most common encapsulating material, EVA, is typically used under conditions where some water molecule transport through the backskin sheet 44 is permitted. Advantageously, moisture is not trapped, and the moisture and known byproducts of EVA decomposition, such as acetic acid, are allowed to diffuse to prolong module material life; for example, by discouraging EVA discoloration.

In various embodiments of the invention, the backskin 44 material includes a breathable polyvinyl fluoride polymer or other polymer to form the moisture permeable material, including polymer materials and layered polymer combinations suitable for use with the invention, as well as those to be developed in the future. A typical moisture permeability index or transmissivity which is typical of breathable backskin material and which is achieved through perforation of the reflective metal film 48 on the reflecting backskin 44 is about one gram through about ten grams per square meter per day. It is to be understood that the approach of the invention can also be used for small molecule migration through a backskin that is permeable to such small molecules.

EVA is typically used with a TPT backskin 44, which defines one class of breathable materials. TPT is a layered material of TEDLAR®, polyester, and TEDLAR®. TEDLAR® is the trade name for a polyvinyl fluoride polymer made by E.I. Dupont de Nemeurs Co. In one embodiment, the TPT backskin 44 has a thickness in the range of about 0.006 inch to about 0.010 inch.

In another embodiment, the backskin 44 is composed of TPE, which is a layered material of TEDLAR®, polyester, and EVA, which is also a “breathable” moisture permeable material.

Typical metal reflector films 48 have a low moisture permeability index. While this may have advantages with encapsulants used in double glass constructions, the lack of moisture permeability is not desirable with a material such as EVA where module lifetime is adversely affected. More specifically, low moisture permeability such as that present with a metallic reflective coating 48 increases the possibility that the moisture byproducts of EVA decomposition will be trapped inside the module. Trapped moisture can increase corrosion of solar cell metallization and moisture transport in and out of the interior of the module may be inhibited to a degree sufficient to significantly degrade module performance with time and shorten the useable lifetime of the module.

According to the invention, the reflecting layer 40, or the composite structure 60, including the reflective coating 48, are perforated to modify the moisture permeability in the regions behind the solar cells 36 (see the moisture permeability areas 66 in FIG. 8). In one embodiment, only the reflective coating 48 is perforated. In another embodiment, any insulating layer or coating associated with the reflecting layer 40 or backskin composite 60 is also perforated. The perforated regions 66 correspond to regions obscured or “shadowed” by the solar cells 36 that do not contribute to reflecting light. For example the perforations 70 can include hundreds of holes of the order of one through ten microns in diameter drilled by a laser. In other embodiments, other methods of perforation are used, such as mechanical (hole puncturing) methods. Alternatively, entire sections or “windows” of metalized film layer which are of the order of the solar cell area from behind the solar cells 36 can be created. (for example, see the moisture permeability areas 66 of FIG. 8).

In one embodiment, the solar cells 36, as shown in the array of solar cells 36 in FIG. 8, are rectangular in shape, with dimensions of about 62.5 millimeters and about 125 millimeters, which are fabricated by cutting square solar cells of 125 millimeters per side in half. In another embodiment, the solar cells 36 have dimensions of about 52 millimeters and about 156 millimeters, which are fabricated by cutting square solar cells 36 of 156 millimeters per side in thirds. The solar cells are spaced about 15 to 30 millimeters apart.

The perforations 70 range in size from one perforation per solar cell 36 (one window per solar cell 36) to numerous small perforations 70 (one micron in diameter or larger). In one embodiment, the moisture control feature of the invention is in a range of about 10 to about 1000 perforations per square centimeter. In various embodiments, perforations 70 can extend into areas between the solar cells 36. In various embodiments, the perforations 70 can vary in size, and in one embodiment can range from about one micron to about 10 microns in diameter for different embodiments. In various embodiments the total area of the perforations 70 ranges from about 0.1 to 1 percent of the total surface area of the reflecting layer 40 (but a larger percentage if a large perforation or windows approach is used, or more moisture permeability is required). In various embodiments, the amount of perforations 70 varies according to the moisture permeability of the backskin 44. In various embodiments, the perforations 70 have various dimensions or shapes (for example, circular, oval, square, rectangular, or other shapes).

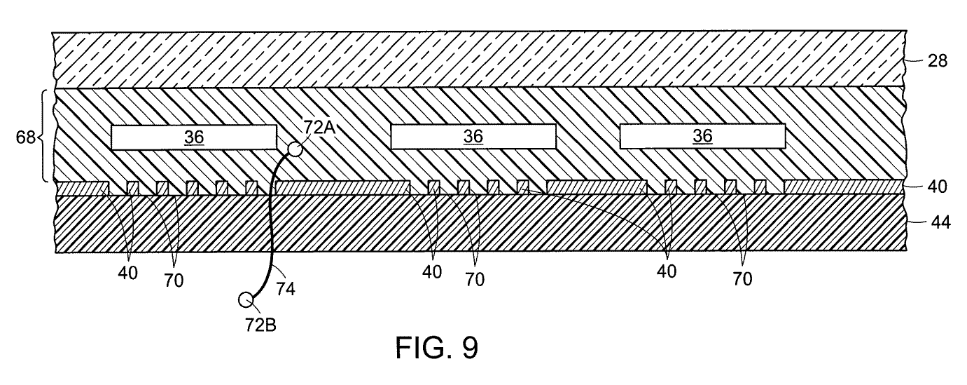

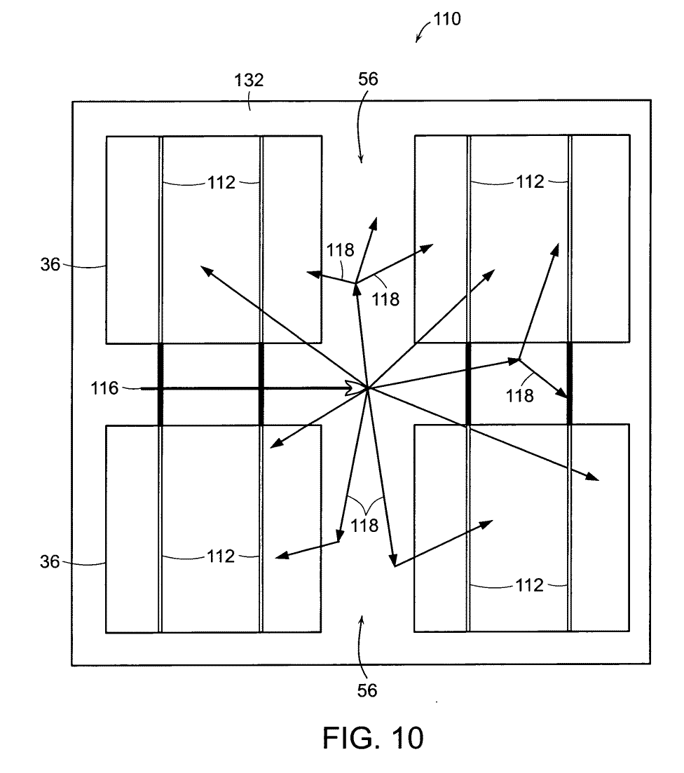

In one aspect, the present invention relates to a structure and methodology for disposing a light redirection layer in a solar electric module. The light redirection layer is an asymmetric redirection layer that redirects incident light in diverse, typically asymmetrical directions. In one embodiment, the light redirection layer is based on light scattering and a light scattering structure or layer is disposed in the solar electric module. FIG. 10 is a plan (overhead) view of a solar electric module 110 including a light scattering structure having a light scattering film 132 according to one embodiment of the invention. The light scattering film 132 is one embodiment of an asymmetric redirection layer for redirecting light. The light scattering film 132 is disposed in spaces 56 between multiple solar cells 36 and redirects incident light 116 (see FIG. 10) from the spaces 56 onto the solar cells 36, thus concentrating redirected light (as redirected light rays, designated generally by the reference numeral 118) onto the solar cells 36. As shown in FIG. 10, solar electric modules 110 comprise multiple solar cells 36 with spaces 56 between adjacent solar cells 36. The solar cells 36 show bus bars 112 on the top of the solar cells 36, which collect electrical current from elongated parallel fingers (not shown in FIG. 10). It is a purpose of the present invention to decrease the cost per watt of the electricity produced by solar electric modules 110 by causing incident light 116 striking the solar electric module 110 in a space 56 between solar cells 36 to be redirected (as redirected light rays 118) to one or more solar cells 36. In the case of a solar electric module 110 having a front glass cover 28 of a given thickness, any light 118 scattered at an angle smaller than the critical angle, which is about 42 degrees, to a normal to the surface, is lost for conversion into electrical power because it exits the front glass cover 28, but any redirected light 118 scattered at a larger angle will be redirected toward an adjacent solar cell 36 by total internal reflection. The critical angle in a first transparent medium (for example, the atmosphere) is dependent on the refractive index of the first medium and the refractive index of the second transparent medium (for example, transparent front cover 28) forming a boundary with the first medium.

In one embodiment the light scattering film 132 is one form of the reflecting layer 40. In another embodiment, the light scattering film 132 is included in a composite backskin. 60.

The light scattering film 132 includes (i) a light scattering surface or light scattering structures within the film 132 and (ii) a light reflecting coating or layer 136 disposed over the back of the film 132. In a preferred embodiment, the light scattering surface comprises a three-dimensional pattern selected to scatter light preferentially at angles greater than the critical angle. In another embodiment, the film 132 contains light scattering structures within the body of the film to scatter light preferentially at angles greater than the critical angle.

In one embodiment, the light scattering methodology of the invention relates to the incorporation of asymmetric or platelet type light reflecting particles into the polymer film 132. These particles, when given suitable electrical or magnetic properties, can be oriented within the film 132, by means of electrostatic or magnetic forces during the film formation process, to impart anisotropic light scattering properties to the film 132. A similar effect can also be achieved if particles are incorporated in the polymer film 132 in a random orientation and the polymer film 132 is then extruded or blown. During the extrusion or blowing process, the platelet particles are oriented in a preferential way. The flat or large surfaces areas of the particles will be preferentially oriented within the film 132 thereby imparting reflective properties not conforming to Lambert's Law. For the film or foil 132 resulting from this process, it may be useful to have a reflective coating or layer 136 on the side opposite to the incident light 116 so that light is reflected and/or scattered in a direction opposite to the incident light 116.

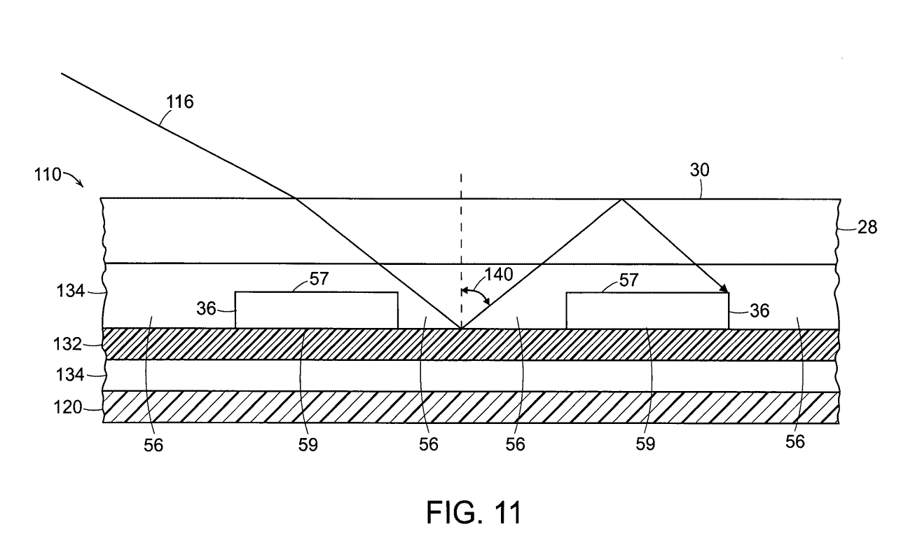

FIG. 11 is a schematic representation of a cross section of a solar electric module 110 illustrating light redirection by a light scattering film 132, in accordance with the principles of the invention. A solar electric module 110 of a preferred embodiment, as shown in FIG. 11, comprises a support structure having a planar surface 120 and a plurality of solar cells 36 overlying the planar surface 120, the cells 36 having front 57 and back surfaces 59 with the back surfaces 59 facing the planar surface 120, the cells 36 being spaced from one another, with predetermined areas 56 of the planar surface 120 free of solar cells 36. The solar electric module 110 further includes a transparent cover member 28, in this embodiment glass, overlying and spaced from the solar cells 36, having front surface 30 disposed toward incident radiation 116, and a light scattering optical film or foil 132 overlying predetermined areas of the planar surface 120. The light scattering film or foil 132 is incorporated within coating layers 134 (for example, an encapsulant material) disposed over the light scattering film or foil 132. The light scattering film or foil 132 includes light reflecting particles selected to scatter incident radiation 116 preferentially with substantial efficiency at angles 140 larger than the critical angle of about 42 degrees. The refraction index of the coating layer 134 is chosen such that when compared to the refractive index of the glass cover number 28, light is allowed to pass through, and not be reflected at, the boundary of the glass cover number 28 and the coating layer 134.

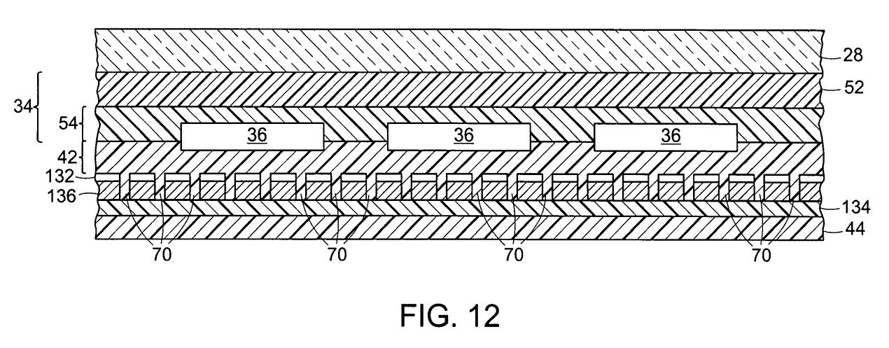

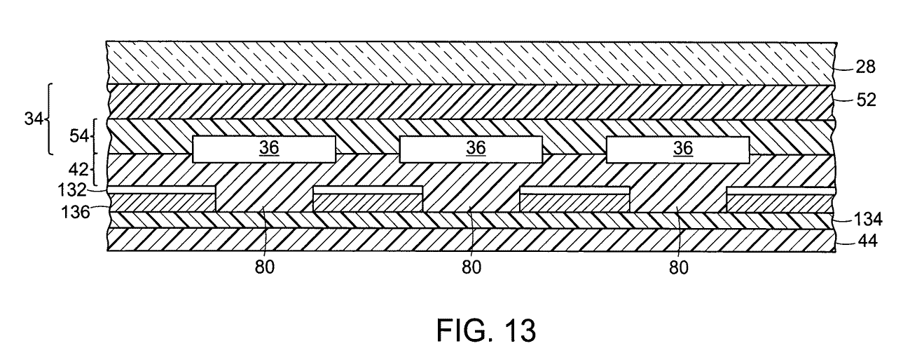

A preferred film or foil structure, which is to have a front glass cover 28, is a polymer film 132 from about 5 to about 1000 micrometers in thickness and transparent in the solar spectrum from about 400 to about 1000 nanometers incorporating a light scattering surface designed to scatter light preferentially at angles greater than the critical angle of about 42 degrees and having a thin light reflective coating or layer over the back of the film or foil 132. In another embodiment, the film or foil 132 incorporates particles, preferably from about 0.1 to about 800 micrometers in diameter, of certain shape and or optical properties to cause light to scatter preferentially at angles greater than the critical angle. In the latter case, a light reflective coating 136 (see FIGS. 12 and 13) is deposited on the side of the film or foil 132 away from the light incident side of the foil or film 132 and the polymer film 132 is light transparent. In one embodiment, the light scattering film 132 is substantially transparent or translucent, because the film 132 includes light scattering particles that may lessen the transparency to a greater or lesser degree. In another embodiment, a light reflective coating or layer 136, composed of a light reflecting metal, (see FIGS. 12 and 13) is a separate layer (for example, metallic reflecting layer, such as aluminum, silver, or other reflecting metal) disposed on the side of the film or foil 132 away from the light incident side of the foil or film 132, and the polymer film 132 is light transparent.

With the present approach of Non-Lambertian light redirection (for example, light scattering), much of the incident radiation 116 incident on the spaces 56 between the solar cells 36 is redirected from the spaces 56 onto the solar cells 36, thus increasing the overall power production of the solar cells 36. Other advantages of the Non-Lambertian light redirection approach include ease of fabrication, low cost of fabrication, ease of use, wide angle of acceptance of the light scattering and light redirecting element 132, and reduction of the necessity of mechanical tracking of the sun by continuous adjustment of the solar module 110 to maintain the effectiveness of the light scattering element 132 over substantial variations in the angle of incidence of solar radiation during passage of the sun during the day.

FIG. 12 is a schematic representation of a cross section of a solar electric module including a weight mitigation layer 52 and moisture control perforations 70 in a light scattering film 132, in accordance with the principles of the invention. The solar electric module also includes a transparent top cover 28, the first transparent layer 34, the solar cells 36, the second transparent layer 42, the light scattering layer 132, a light reflective coating or layer 136, coating layer (also termed “encapsulant layer”) 134, and backskin 44. The first transparent layer includes a weight mitigation layer 52 and encapsulant sheet 54.

In various embodiments, the reflective coating or layer 136 (shown, for example, in FIGS. 12 and 13) is optional. In one embodiment, the light scattering film 132 includes a larger number or concentration of light reflecting particles, so that the incident light 116 has a very small probability of passing through the light scattering film 132 without striking a light reflecting particle. In another embodiment, the light scattering film 132 includes a relatively small number or concentration of light reflecting particles, so that incident light 116, in some cases, passes through the light scattering film 132 and strikes the reflective coating or layer 136 without striking any light reflecting particles. The light scattering film 132 includes a smaller number or concentration of light reflecting particles, to provide the advantage of reduced costs. In one embodiment, the light scattering film 132 includes pigment particles 10 percent by weight for a film that is 0.005 inches thick.

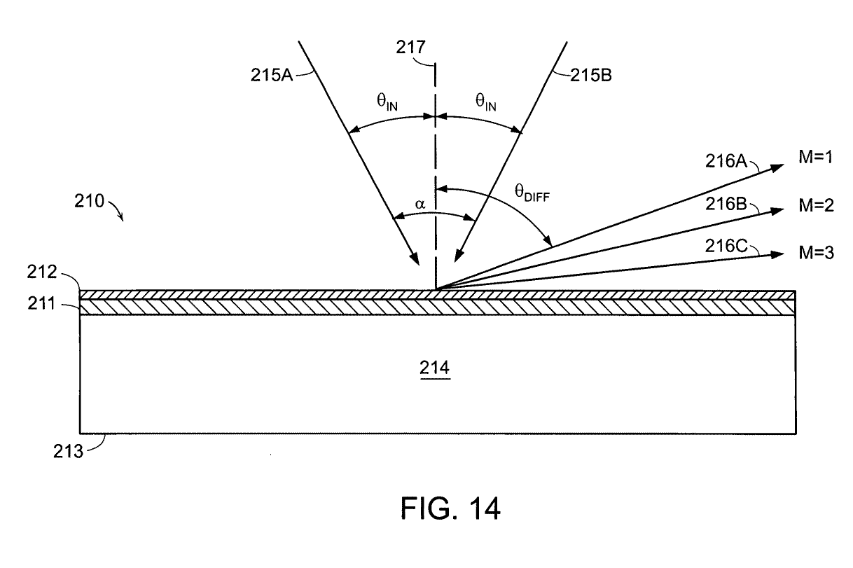

In various embodiments, a light scattering film 132 with a relatively low number or concentration of light reflecting particles is combined with reflecting layers of various types. That is, the reflective coating or layer 136 is a reflecting layer (for example, metallic layer, such as aluminum or silver), grooved reflecting layer 40 (see, for example, FIG. 2), a composite backskin 60 (see, for example, FIG. 7); diffractive structure 210 (see, for example, FIG. 14), a white surface based on any suitable material, or other suitable reflecting layer or structure, as well as reflecting layers to be developed in the future.

In one embodiment, the encapsulant layer 134 (shown, for example, in FIGS. 12 and 13) also serves as a supporting layer for the light scattering film 132 and reflective coating or layer 136, or as a supporting layer for the light scattering film 132 alone (if no reflective coating or layer 136 is provided).

The light scattering layer 132 and reflective coating or layer 136 have perforations 70 that extent through both layers 132, and 136. The perforations 70 allow for the migration of moisture from the solar electric module (for example, from the transparent (encapsulant) layers 34 and 42), through the encapsulant layer 134 and backskin 44 out of the solar electric module (for example, see FIG. 9). The encapsulant layers 42, 54, and 134 must be layers that are moisture permeable (for example, a polymer material such as EVA). The backskin 44 must be a layer that is also moisture permeable, as discussed elsewhere herein.

In another embodiment, the perforations 70 extend through the reflecting reflective coating or layer 136 only. In this embodiment, the light scattering layer 132 must be moisture permeable; for example, a polymer layer, such as EVA, that is moisture permeable and includes light scattering particles. The light scattering particles do not prevent or interfere with moisture permeability. In one embodiment, the light scattering particles (for example, metallic or other particles) are encased in a plastic or epoxy material (before inclusion in the light scattering film 132) that prevents interactions between the light scattering particles and moisture migrating through the light scattering film 132.

In one embodiment, the perforations 70 are disposed only in areas beneath the solar cells 36 (not shown in FIG. 12). For example, see FIG. 9.

In one embodiment, the solar electric module (shown for example in FIGS. 12 and 13) includes a weight mitigation layer 52 (as also shown in and discussed for FIGS. 2-6). FIGS. 12 and 13 are not meant to be limiting of the invention, the approach of the invention does not require that a weight mitigation layer 52 be provided in the same solar electric module as a moisture control approach (that is, a weight mitigation layer 52 is not required to be included with perforations 70 and/or windows 80).

FIG. 13 is a schematic representation of a cross section of a solar electric module including a weight mitigation layer 52 and moisture control windows 80 in a light scattering film 132, in accordance with the principles of the invention. The moisture control windows 80 are centered underneath the adjacent solar cell 36, and are typically smaller in size that the solar cells 36 (for example, 90 percent or less the size of the solar cells 36). See, for example, FIG. 9.

The light scattering layer 132 and reflective coating or layer 136 have windows 80 that extent through both layers 132, and 136. The windows 80 allow for the migration of moisture from the solar electric module (for example, from the layers 34, and 42), through the encapsulant layer 134 and backskin 44 out of the solar electric module (for example, see FIG. 9). The encapsulant layers 42, 54, and 134 must be layers that are moisture permeable (for example, a polymer material such as EVA). The backskin 44 is a layer that is also moisture permeable, as discussed elsewhere herein.

In another embodiment, the windows 80 extend through the reflecting reflective coating or layer 136 only. In this embodiment, the light scattering layer 132 must be moisture permeable; for example, a polymer layer, such as EVA, that is moisture permeable and includes light scattering particles. The light scattering particles do not prevent or interfere with moisture permeability. In one embodiment, the light scattering particles (for example, metallic or other particles) are encased in a plastic or epoxy material (typically before inclusion in the light scattering film 132) that prevents interactions between the light scattering particles and moisture migrating through the light scattering film 132.

In one embodiment, the light scattering layer 132 is based on a thin layer of pot opal, a material consisting of very small colorless particles imbedded in a clear glass matrix throughout its entire thickness. In another embodiment, very small colorless (or otherwise reflective) particles are imbedded in a clear plastic matrix (for example, EVA) throughout its entire thickness. The light scattering characteristic of the scattering light film 132 is such that the intensity of the scattered light is nearly constant from zero degrees to the critical angle and drops off only gradually until an angle of about 70 degrees has been reached, which deviates strongly from Lambert's law. The light scattered at angles smaller than the critical angle is lost, but light scattered at larger angles is redirected toward adjacent solar cells 36. This useful fraction of the incident light 116 can be as high as 50 percent, depending on the preferential light diffusion or scattering properties of the light scattering layer 132.

In one embodiment, the light scattering film 132 is based on mica particles. The mica is crushed to produce a powder material and placed in a carrier such as epoxy, or, in one embodiment, a polymer, such as EVA.

In another embodiment, the light scattering film 132 is based on small bubbles in the film 132. The light scattering film 132 is manufactured from a glass or plastic material in such a way that small bubbles of a predetermined size form in the light scattering film 132. The small bubbles are of such a predetermined size that some bubbles break the surface of the light scattering film 132 and form the perforations 70.

In one embodiment, the perforations 70 are located throughout the light scattering film 132 and reflective coating or layer 136, including areas 56 between the solar cells 36. The perforations 70 cause open (nonreflecting) areas that are, in one embodiment, no more than about one percent or two percent of the area of the light scattering film 132.

In one embodiment, the inclusion of a reflective coating or layer 136 that is metallic or otherwise electrically conducting requires the inclusion of a insulation layer to prevent the metallic reflective coating or layer 136 from making an electric connection to the solar cells 36, conductors 112 associated with the solar cells 36, and/or contacts associated with the back surfaces 59 of the solar cells 36. If such an insulation layer is included and it is not permeable to moisture, then perforations 70 or windows 80 must extend through the insulation layer. In other embodiments, an insulation layer or material is associated with the contacts and conductors 112 to prevent an electrical connection with an electrically conducting reflective coating or layer 136.

In one aspect, the present invention relates to a structure and methodology for disposing a light redirection layer in a solar electric module. The light redirection layer is a symmetric light redirection layer that redirects incident light in diverse, typically symmetrical directions or modes. In one embodiment, the symmetric redirection layer includes a diffraction optical element or member based on a surface having a diffractive relief pattern. In general, the diffractive light redirection aspect of the present invention is based on use of a class of structures in the field of optics generally referred to as spatial light modulators, diffractive optical elements, or holographic optical elements.

FIGS. 14 through 21 and related discussions herein are based on U.S. Published Patent Application 2004/0123895, titled “Diffractive Structures for the Redirection and Concentration of Optical Radiation,” by Michael J. Kardauskas and Bernhard P. Piwczyk.

FIG. 14 illustrates an embodiment of a diffractive structure (diffractive optical element or member) 210 comprising a substrate 214 having a top surface 211 and a bottom surface 213. The diffractive structure 210 is one embodiment of a symmetric redirection layer for redirecting light. The top surface 211 has a topographical surface relief pattern, while the bottom surface 213 contains no relief pattern. The substrate 214 can be plastic film or other suitable material. A thin coating layer 212 is disposed over the top surface 211. The coating layer 212 is preferably metallic, such as aluminum or silver. The metallic coating layer 212 may in turn be overcoated with a thin layer of silicon oxide (SiO₂), aluminum oxide (Al₂O₃), magnesium fluoride (MgF), or a polymer to prevent oxidation and/or corrosion, and to provide electrical insulation.

The diffractive structure 210 depicted in FIG. 14 is useful in providing a desired redirection operation with respect to incoming radiation. In particular, for a wide range a of incidence angles θ_{IN} with respect to surface normal 217, the surface relief pattern diffracts incident radiation with substantial efficiency into one or more diffraction orders. The diffracted radiation is redirected from the structure 210 in selected directions at angles that are greater than a selected angle with respect to the surface normal 217. For example, the incident plane waves 215A, 215B are redirected at first order diffraction mode indicated by plane wave 216A at angle θ_{DIFF}. The surface relief pattern may also diffract the incident radiation at second and third orders as shown for plane waves 216B and 216C, respectively, or at still higher orders, depending on the configuration of the kinoform (that is, surface relief pattern of the top surface 211).

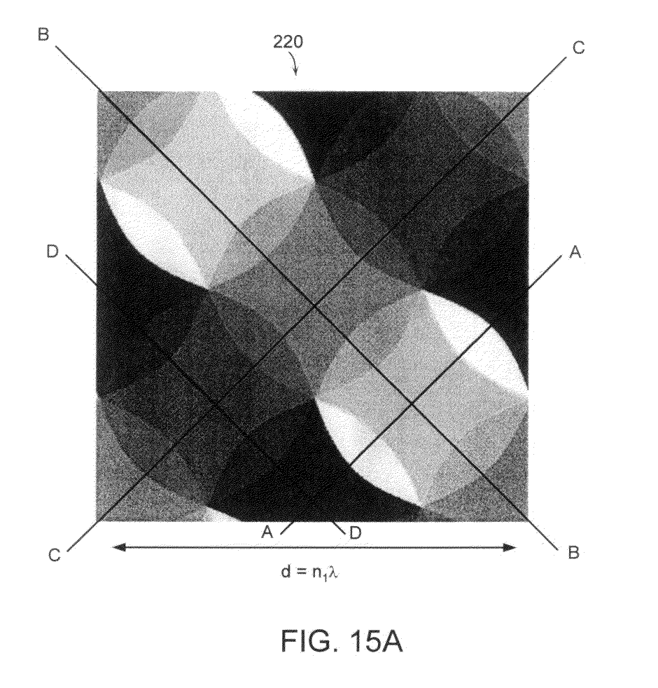

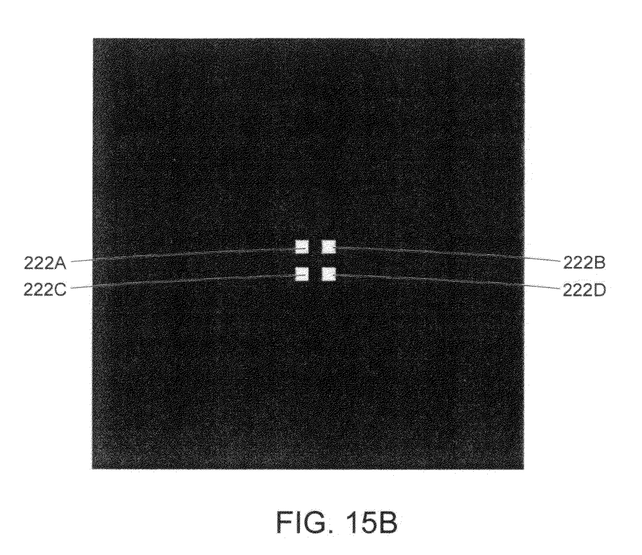

An exemplary surface relief pattern is shown in FIG. 15A. The particular pattern shown is a phase template 220 selected to redirect incident radiation into four second order symmetric diffraction modes and to eliminate redirection of incident radiation of the first order. A diffraction plane view resulting from incidence of a single square beam of light onto the pattern of FIG. 15A is illustrated in FIG. 15B. Four second order modes 222A, 222B, 222C, 222D are shown. The first order is eliminated by cancellation or destructive interference. In general, a diffractive optical element (DOE) is a component that modifies wavefronts by segmenting and redirecting the segments through the use of interference and phase control. A kinoform is a holographic optical element (HOE) or DOE which has phase-controlling surfaces. A binary optic is a simple DOE that features only two phase-controlling surfaces, which introduce either a 0 or ¼ phase difference to the incident wavefront. When there are N masks, a multilevel binary optic or MLPR DOE can be generated, usually resulting in 2^{N} phase levels. In particular, a multilevel DOE is formed from multiple layers of material of differing thicknesses, such that the layers are combined in various combinations to produce more levels than there are layers. For example, by depositing layers a, b, and c, which are all of different thicknesses, then there can be distinct levels corresponding to 0 (no deposited material), a, b, and c, and also a+b, a+c, b+c, and a+b+c. Thus, depositing N=3 layers can produce 2³ or 8 levels.

The phase template 220 shown in FIG. 15A contains two unit cells, one unbroken in the center of the image and one broken up into 45/90 degree triangles at the four corners of the image. The unit cell is of length d=2λ where λ is the shortest design wavelength of interest. In embodiments, the diffractive pattern comprises repeating unit cell structures that may have lateral dimensions of between 400 nanometers and 4000 nanometers.

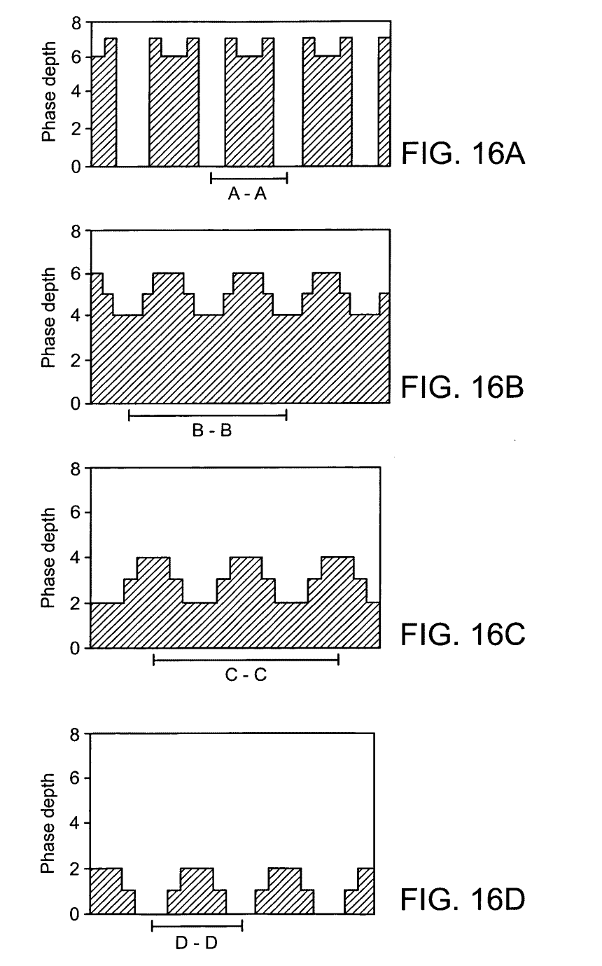

The phase template 220 can be understood as a DOE that has eight equal phase levels of π/8 each and can be generated using three masks, as described further herein. Profiles of the phase depths taken along lines A-A, B-B, C-C, and D-D are illustrated in FIGS. 16A-16D, respectively. For example, the profile taken along line A-A includes transitions from 0 to 7, 7 to 6, 6 to 7, and 7 to 0 phase depth, as shown in FIG. 16A. Cells that adjoin the cell structure shown in FIG. 15A continue with this phase profile. Likewise, the profile taken along line B-B includes a repeating pattern of phase depth transitions from 4 to 5, 5 to 6, 6 to 5, and 5 to 4 (FIG. 16B). The profile taken along line C-C repeats a pattern of phase transitions from 4 to 3, 3 to 2, 2 to 3, and 3 to 4 (FIG. 16C). The profile taken along line D-D has a repeating pattern of transitions from 0 to 1, 1 to 2, 2 to 1, and 1 to 0 (FIG. 16D).

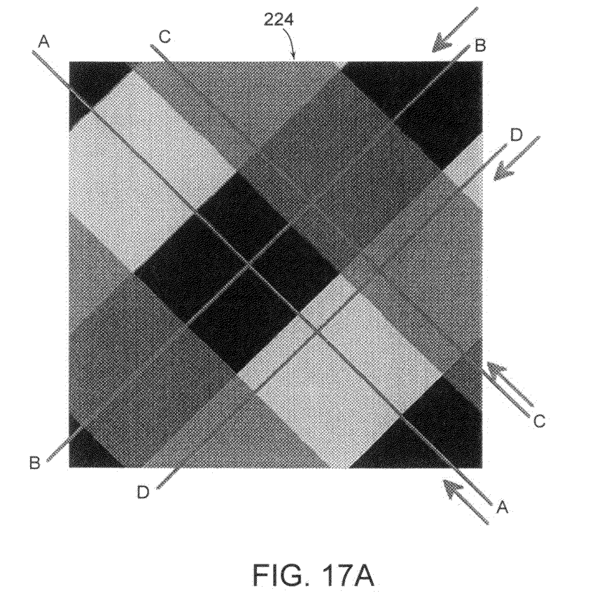

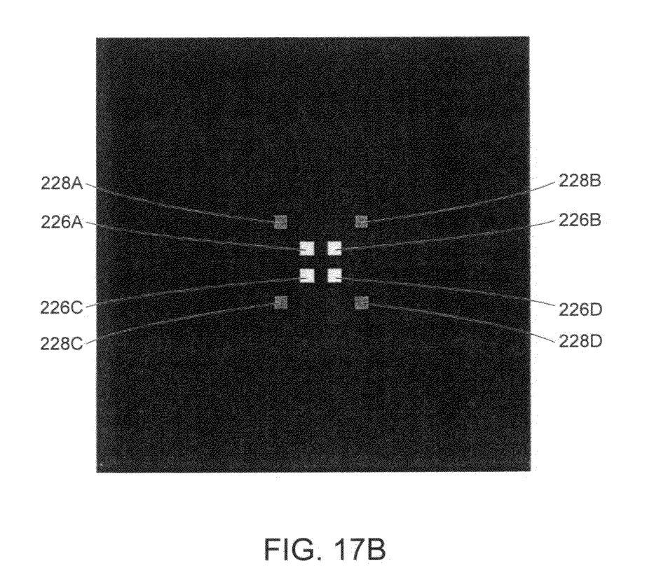

Another exemplary surface relief pattern is shown in FIG. 17A. The particular pattern shown is a four level phase template 224 generated using two masks, with phase levels of π/2. The phase template 224 also redirects incident radiation into four second order symmetric diffraction modes and eliminates redirection of incident radiation of the first order. A diffraction plane view resulting from incidence of a single square beam of light onto the pattern of FIG. 17A is illustrated in FIG. 17B. Four second order modes 226A, 226B, 226C, 226D are shown. In addition, the diffraction from the pattern of FIG. 17A results in third order modes 228A, 228B, 228C, 228D.

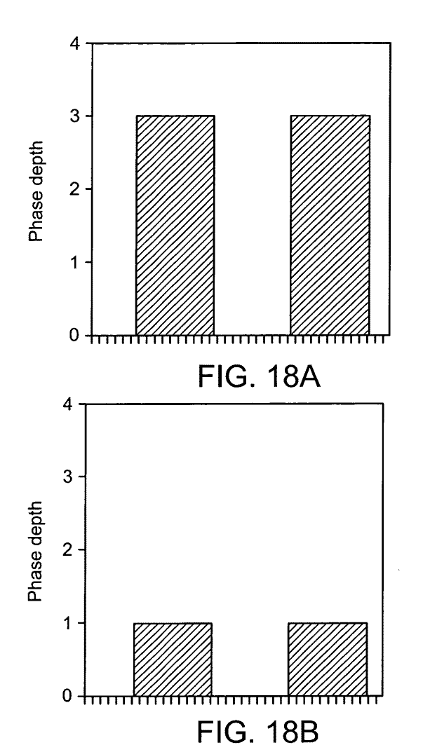

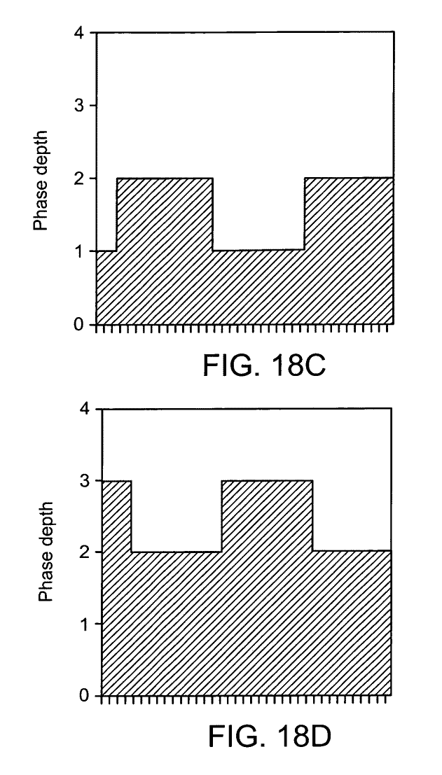

Profiles of the phase depths of the pattern of FIG. 17A taken along lines A-A, B-B, C-C, and D-D are illustrated in FIGS. 18A-18D, respectively. For example, the profile taken along line A-A includes transitions from 0 to 3, 3 to 0, 0 to 3, and 3 to 0 phase depth, as shown in FIG. 18A. Cells that adjoin the cell structure shown in FIG. 17A continue with this phase profile. Likewise, the profile taken along line B-B includes a repeating pattern of phase depth transitions from 0 to 1, 1 to 0, 0 to 1, and 1 to 0 (FIG. 18B). The profile taken along line C-C repeats a pattern of phase transitions from 1 to 2, 2 to 1, and 1 to 2 (FIG. 18C). The profile taken along line D-D has a repeating pattern of transitions from 3 to 2, 2 to 3, and 3 to 2 (FIG. 18D).

The exemplary patterns shown in FIGS. 15A and 17A are of the multilevel type. However, it should be understood that DOEs of the kinoform type that can be computed to provide similar redirection results are also contemplated. Those skilled in the art will appreciate that an increase in the number of levels of the DOE can result in a decrease in the number and intensity of the secondary reflections, which can increase the amount of light directed in useful (rather than non-useful) directions. While the patterns described redirect incident radiation into four symmetric modes, it will be appreciated that redirection of incident radiation into two, three, five, six or more modes can also achieve the desired optical results of the present invention. In some embodiments, the diffracted directions may be, for example, two directions that are 180 degrees apart, six directions at least 20 degrees apart from one another, or eight directions at least 15 degrees apart from one another.

The phase template views (FIGS. 15A, 17A) and the diffraction plane views (FIGS. 15B, 17B) were generated using AMPERES diffractive optics design tool provided by AMP Research, Inc., Lexington, Mass.

There exists a broad range of manufacturing techniques over a large choice of media for the fabrication and replication of the diffractive structures described herein. Microlithographic fabrication technologies include mask patterning using laser-beam writing machines and electron-beam pattern generators, photolithographic transfer, ion milling, deep exposure lithography, and direct material ablation. Fabrication techniques include conventional mask alignments using simple binary masks, grey-tone masking, direct write methods, and LIGA processes. Replication of the DOE master can be accomplished using any of the conventional replication techniques, including plastic embossing (hot embossing and embossing of a polymer liquid, followed by UV curing) and molding processes. These technologies and techniques are described in detail in the aforementioned “Digital Diffractive Optics—An Introduction to Planar Diffractive Optics and Related Technology,” B. Kress and P. Meyrueis.

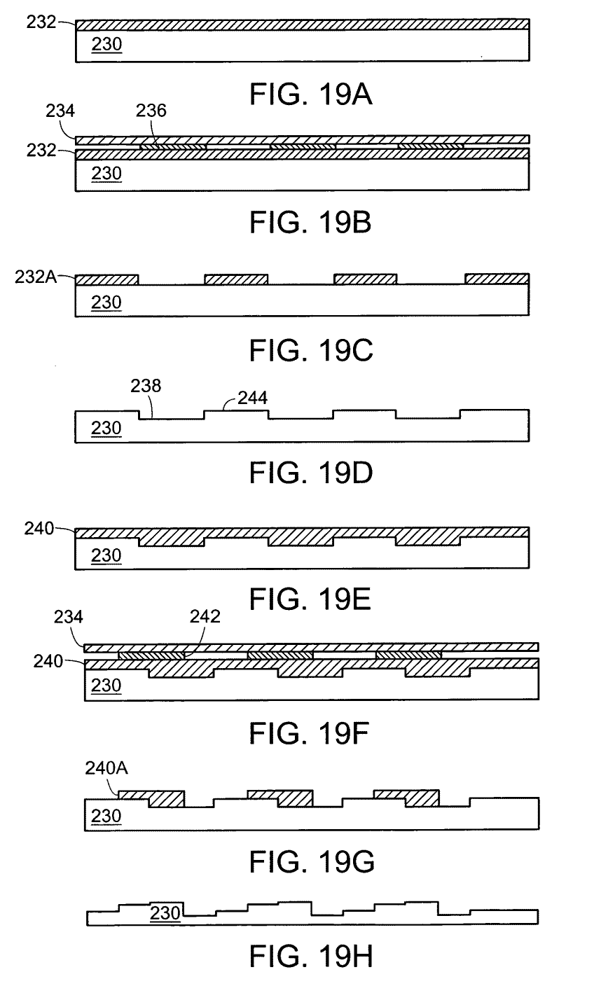

An exemplary method for fabricating a master for a four level diffractive structure of the type shown in FIG. 17A using conventional semiconductor processes is now described with reference to FIGS. 19A-19H. The process starts (FIG. 19A) with a material blank 230 such as a flat plate of high quality quartz or silicon. The blank 230 is coated with a suitable photoresist 232 capable of the required resolution and able to withstand ion milling. Ion milling is a process in which ions (usually argon) are accelerated so that they impinge on the target substrate with sufficient energy to cause atoms of the target material to be dislodged so that the target material is eroded or “etched”. An alternative method is known as “reactive ion etching”.

The photoresist 232 is exposed (FIG. 19B) using a chrome mask or photomask 234 that carries the required image 236 of the first level required to produce the desired diffractive pattern. Exposure can be performed using common semiconductor fabrication exposure equipment such as wafer steppers or step and scan systems available from ASM, Ultratech, Cannon and others. The image required for mask generation can be computed by diffractive optical element generating software obtainable from various commercial sources (for example, Code V from Optical Research Associates, Pasadena, Calif.; Zemax from Zemax Development Corporation, San Diego, Calif.; or CAD/CAM design tools from Diffractive Solutions, Neubourg, France) and can be generated using standard chrome photomask making technology for semiconductor circuit fabrication employing commercial mask generating equipment such as MEBES or CORE 2000 marketed by Applied Materials, Inc. In most cases it may be necessary to convert the DOE design output data into a format needed for driving a given mask generation system. FIG. 19B shows a contact printing process which can also be performed by wafer stepper technology.

A standard chemical developer having the desired characteristics needed to develop the chosen photoresist is used to produce a relief pattern 232A as shown in FIG. 19C. The resist relief pattern 232A is transferred into the substrate 230 by ion milling that can be performed by equipment commercially available from VEECO Corporation, for instance. Note that the resist 232A functions as a mask to shield the resist-covered areas from impinging ions. The areas 238 (FIG. 19D) not covered by the resist 232A are eroded or etched by a flood ion beam and the resist 232A is also eroded at the same time but not at the same rate. The erosion rate of the substrate material 230 is generally slower than that of the resist 232A. Etching can be performed to any depth as long as the resist 232A is not completely eroded or etched away. For very deep etching the resist thickness needs to be commensurate with the desired depth required. Shallow ion milling or etching can also be performed but any residual resist needs to be removed chemically afterwards.

To produce the next diffractive pattern level, the substrate 230 is coated with a second layer of photoresist 240 (FIG. 19E). A second resist exposure step (FIG. 19F) with mask 234 carrying image 242 follows. The photoresist 240 is exposed and results in the second resist pattern. The second pattern is precisely aligned with respect to the first exposure. The photoresist is developed with the resulting relief pattern 240A illustrated in FIG. 19G. Ion milling follows and results in the four level structure illustrated in FIG. 19H. The above-described process can be repeated using an increased number of mask levels in order to improve performance criteria, such as efficiency and brightness. Note that the use of two masks results in four levels, three masks produce eight levels, etc.

The master produced by the above-described processes can be used to fabricate a “shim” by plating a layer of nickel on top of the master using either an electrolytic or an electroless process and then removing the nickel replica. The fabricated shim, which is a negative of the master, is then used to generate a stepped and repeated pattern in a larger plate of softer material by stamping or embossing. The plate is then used to produce a shim of the desired size, again by nickel plating. This larger shim can then be put onto a drum that may then be employed to emboss the diffractive pattern onto large rolls of polyethylene terephthalate (PET), polycarbonate, acrylic, or any other suitable film in volume production. Alternatively, the larger shim may be applied to a flat press, which is then used to emboss the diffractive pattern onto flat sheets of the above-named materials.

Those skilled in the art will appreciate that the diffractive structure can be formed as a surface hologram having the desired diffractive properties. Other techniques for forming a diffractive structure include using electron beam lithography, or an optical pattern generator.

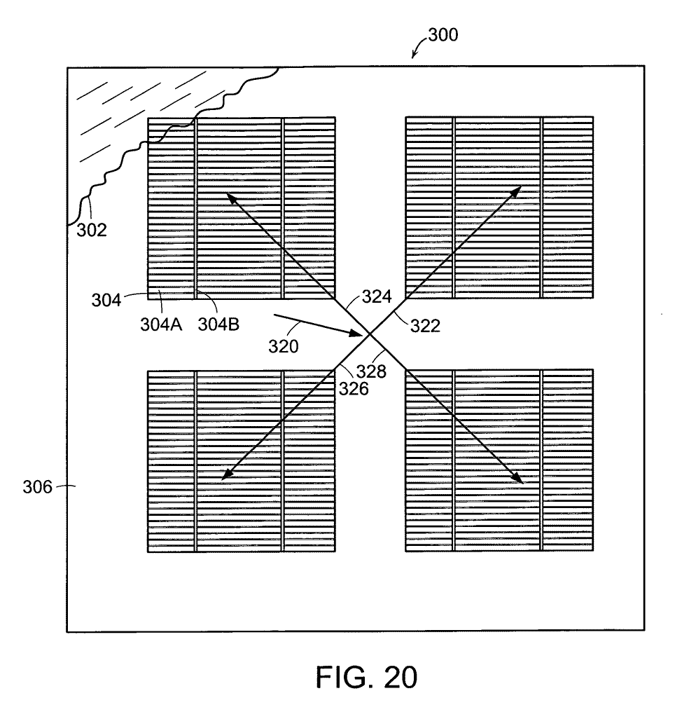

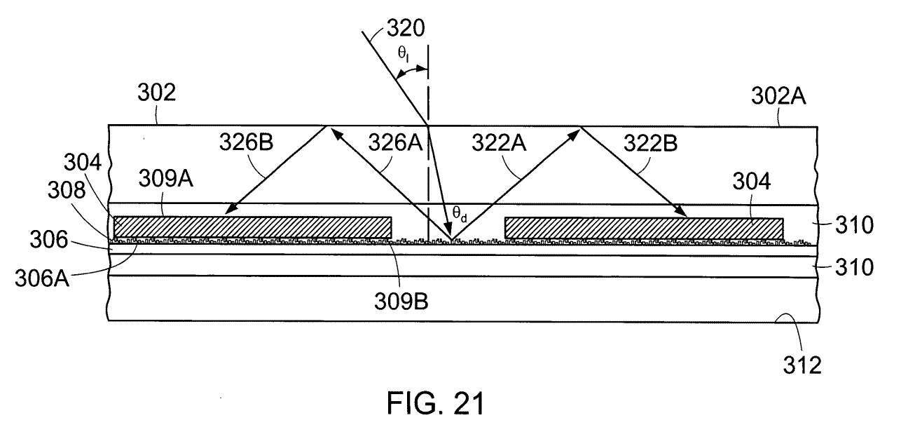

FIGS. 20 and 21 are top plan and cross-sectional views, respectively, that illustrate an embodiment of a solar cell module 300 that incorporates a diffractive structure (diffractive optical element or member) of the present invention. The solar cell module 300 includes a plurality of rectangular solar cells 304 having respective front and back surfaces 309A, 309B. The type of solar cells 304 used in the module 300 may vary and may comprise, for example, silicon solar cells 304. Each solar cell 304 has on its front surface 309A a grid array of narrow, elongate parallel fingers 304A interconnected by one or more bus bars 304B. The solar cells 304 are arranged in parallel rows and columns, and are electrically interconnected in a series, parallel or series/parallel configuration, according to the voltage and current requirements of the electrical system into which the module 300 is to be installed. The solar cell module 300 includes a diffractive optical member 306. The diffractive optical member 306 is one embodiment of a symmetric redirection layer for redirecting light.

Overlying the cells 304 is a stiff or rigid, planar light-transmissive and electrically non-conducting cover member 302 in sheet form that also functions as part of the cell support structure. The cover member 302 has a thickness in the range of about ⅛ inch to about ⅜ inch, in one embodiment, at least about 3/16 inch, and has an index of refraction between about 1.4 and 1.6. By way of example, cover member 302 may be made of glass or a suitable plastic such as a polycarbonate or an acrylic polymer. The module 300 also includes a back protector member in the form of a sheet or plate 312 that may be made of various stiff or flexible materials; for example, glass, plastic sheet or plastic sheet reinforced with glass fibers.

Disposed below the back surface 309B of solar cells 304 is a diffractive optical member 306 comprising a substrate 306A that has a diffractive topographical relief pattern with a thin metallic coating layer on its top surface 308. In one embodiment, the pattern can be of the type described above with respect to FIGS. 15A and 17A. The substrate 306A is made of a plastic film material which may be of either the thermoplastic or thermosetting type, on which additional layers, such as of an embossed UV-cured coating, may be applied, and which may be transparent, translucent or opaque. The diffractive optical member 306 is fabricated in accordance with the principles described above for redirecting incident radiation at selected angles. The coating layer is selected to have an index of refraction that is substantially different from that of the substrate 306A, such as, by way of example, metals such as aluminum or silver. The metallic coating layer may in turn be overcoated with a thin layer of silicon oxide (SiO₂), aluminum oxide (Al₂O₃), magnesium fluoride (MgF), or a polymer to prevent oxidation and/or corrosion, and to provide electrical insulation. In other embodiments, the diffractive optical member 306 can be disposed such that the diffractive pattern and coating layer are on the bottom surface facing away from the solar cells, rather than the top surface, so as to avoid any possibility of the metal film short-circuiting the cells 304. In such embodiments, the substrate 306A is substantially transparent and is selected to have an index of refraction that closely matches the index of refraction of the cover member 302.

As illustrated in FIG. 20, the diffractive optical member 306 extends across the spaces between adjacent cells 304 and also any spaces bordering the array of cells 304. Note that in other embodiments the diffractive optical member 306 can be disposed substantially co-planar with the solar cells 304.

Interposed between back sheet 312 and transparent cover member 302 and surrounding the cells 304 and the diffractive optical member 306 is an encapsulant 310 made of suitable light-transparent and electrically non-conducting material, such as ethylene vinyl acetate copolymer (known as “EVA”) or an ionomer. The index of refraction of the encapsulant 310 is selected to closely match that of the cover member 302 and that of the substrate 306A. The refractive index of the polymeric encapsulant 310 is in the range of 1.4 to 1.6 depending on the specific chemical formulation. The substrate 306A of the diffractive optical member 306 is made from a suitable polymer material meeting a variety of other required physical parameters (for example, resistance to UV radiation, resistance to moisture, strong adhesion to encapsulant, etc.) which has a refractive index in the same general range of the encapsulant 310. If the substrate 306A is brought in optical contact with the encapsulant 310 and the diffractive indexes of both materials are the same or approximately the same, the optical property of the diffractive surface 308 would be nullified since the surface topography would be “filled in” by the encapsulant 310, thus making the diffractive surface essentially ineffective to incident radiation 320.

This problem is overcome by coating the surface pattern 308 with a thin layer of material such as a metal (aluminum or silver are preferred). A thin layer of about 200 Angstroms (0.02 microns) is sufficient and does not change the properties of the diffractive optical member 306 substantially. This metal layer provides a discontinuity in the refractive index or a large index mismatch at the interface between the metal and the polymer encapsulant so that the diffractive optical member 306 continues to function optically. Alternatively a multilayer optical coating having reflective properties over a broad portion of the solar spectrum can be used instead of a metallic coating. A multilayer optical coating, however, is generally more expensive than a single reflective metallic coating.

In operation, as illustrated in FIGS. 20 and 21, incident radiation 320 impinges on the diffractive optical member 306 between and around the cells 304 in the module 300 at an incident angle θ₁. The surface relief pattern 308 diffracts the incident radiation 320 with substantial efficiency into four higher order symmetric diffraction modes with no diffracted radiation of the first order. The plane waves 322, 324, 326, 328 indicate the four symmetric diffraction modes. The diffracted radiation is redirected from the diffractive structure 306 in selected directions at angles that are greater than the minimum angle, θᵢ, with respect to the surface normal, that results in total internal reflection at the interface between the transparent cover member 302 and the air above it. The size of this angle can be calculated as:

sin θᵢ=n₂/n₁,

where n₂ is the index of refraction of air and n₁ is the index of refraction of the cover member 302, and for n₂=1 and n₁=1.5, then θᵢ is about 42 degrees.

For a pattern selected of the type shown in FIG. 15A, the features of the pattern can be understood as follows. Let the length of a side of the unit cell be Λ. The wave vector of the diffraction modes at second order makes an angle θ with respect to the surface normal given by

$$tan θ = \frac{2 ( \frac{λ}{Λ} )}{\sqrt{{n}^{2} - 4 {( \frac{λ}{Λ} )}^{2}}}$$

where n≈1.5. Thus, if we take

Λ=2λ,

then θ=θᵢ. λ is the wavelength and is preferably selected towards the smaller end of the band, since, for a given Λ, longer wavelengths will correspond to larger diffraction angles. For design wavelengths in the range of solar radiation, it is expected that the sum of the diffraction efficiencies for the four modes is greater than about 80%.

The operation shown in FIG. 21 for plane waves 322 and 326 indicates diffracted radiation plane wave 322A at angle θ_{D}>θᵢ is totally reflected back as plane wave 322B to the solar cell 304.

In this manner, substantially all of the incident radiation 320 that is incident on the diffractive surface 308 disposed between the solar cells 304 is redirected by diffraction at the surface 308 and by reflection at the top cover surface 302A onto the solar cells 304. Thus, power production from the solar cells 304 is increased above the level that such cells 304 would normally produce if the radiation 320 impinging on spaces between the cells 304 were not available.

Since the area in the solar module 300 between the cells 304 is much less costly to produce than the area covered by the solar cells 304, the difference being the cost of the solar cells 304, substantial cost savings are possible in the production of solar generated electrical power using the present approach. Actual tests have demonstrated a power output increase of about 20 percent with 10 cm square cells spaced 2.5 cm apart. Calculations show that changes in the design of the diffractive surface, combined with a further increase in the spacing between the cells 304, may increase this to 100% or more.

While the distance traveled by a redirected light beam parallel to the surface of the solar module 300 differs as a function of the wavelength of the impinging light 320 when this redirection is accomplished through diffraction, an effect that does not occur in designs employing specular or diffuse reflection, this does not detract from the usefulness of the diffractive method, and, in fact, can allow for collection of part of the solar spectrum from portions of the land area 56 between solar cells 304 that are too distant from any solar cell 304 for the entire spectrum to be collected. This is an advantage not shared by designs relying on either specular or diffuse reflection.

The use of diffraction for the present application permits a very wide angle of acceptance; that is, incident radiation 320 is diffracted with relatively high optical efficiency over wide variations in the angle of the incident light 320 with respect to the diffractive member, and shadowing of the redirected light by geometrical elements essential to the design of the light-redirecting element, particularly at high angles of incidence with respect to the surface normal, as encountered with reflective surfaces relying on specular or diffuse reflection, is essentially avoided. Such shadowing is defined as the interception by a geometric feature of the reflecting surface of light that has previously been redirected in the desired direction by another element of the reflecting surface, such that the light no longer travels in the desired direction. It will be appreciated that such an effect occurs in designs relying on specular or diffuse reflection to a greater extent as the angle of incident light with respect to the normal to the plane of the light-redirecting element increases. This effect limits the effective angle with respect to the normal to the plane of the light-redirecting element at which a specular or diffuse reflector can efficiently redirect light, and this, in turn, limits the land area 56 from which such a reflector can efficiently collect radiation for the purpose of redirecting it to a solar cell 304. Because diffractive designs do not suffer from the shadowing effect, they can, in principle, collect light from larger land areas 56 within a solar module 300 than can designs relying on specular or diffuse reflection, producing greater economic benefit. As an additional benefit, much of the light which does not intercept a solar cell 304 after being first redirected by the diffractive element and then reflected from the interface between the cover member 302 and the overlying air, and which then strikes the diffractive element at a second location, will again be redirected by the diffracting element in a useful direction, so that it eventually strikes a solar cell 304 in the solar cell array. Because of the shadowing effect in designs relying on specular or diffuse reflection, those designs generally redirect very little light in useful directions after a first reflection from the interface between the cover member 302 and the overlying air.

An embodiment of the diffractive optical member 306 can be produced in several steps. First, the film 306A that serves as the substrate is manufactured as a sheet having smooth upper and lower surfaces. The sheet 306A may then be wound onto a roll for subsequent processing, or it may be passed directly to subsequent processing stages. The subsequent processing comprises first embossing or patterning the film 306A with a master so as to form a diffractive optical surface, and then coating the diffractive surface with metal or a multi-layer dielectric layer.

The embossing or patterning of the film 306A can be accomplished by passing the film 306A between a pinch roller and an embossing roller, the pinch roller having a smooth cylindrical surface and the embossing roller having a negative of the desired optical pattern on its cylindrical surface. The film 306A is processed so that as it passes between the two rollers the surface is shaped by the pattern on the embossing roller. After formation of the diffractive pattern, the plastic film 306A may be subjected to a metallization process such as a conventional vapor deposition or sputtering process.

As noted, the diffractive optical member 306 is disposed so that it occupies the spaces 56 (“land areas”) between cells 304 in a module 300. Because of the diffractive properties of the diffractive surface pattern, light redirected from one area of the pattern is not blocked by any adjacent area, as can occur in known reflection based systems whenever the incident light 320 arrives from angles other than directly normal to the plane of the reflective element. In addition, a wide angle of acceptance is made possible with the use of the diffractive pattern. Thus, in the present diffractive system, light redirected from the pattern and passing into the transparent cover member 302 strikes the front face 302A of the cover member 302 at an angle exceeding the critical angle, with the result that substantially all of the reflected light is reflected internally back toward the solar cells 304, thereby substantially improving the module's electrical current output.

The diffractive optical member 306 can be assembled into a solar module 300 so as to take advantage of its properties during the module lamination process commonly used to assemble solar modules 300. In this process, the solar cells 304 become bonded to the transparent cover 302 of the module 300, and to a bottom protective covering 312, by means of sheets or films of polymeric material 310, which are provided between the solar cells 304 and the transparent covering 302, and also between the solar cells 304 and the rear side protective covering 312. As the entire assembly 300 is then heated in vacuum, the polymer layers 310 melt, causing all of the components of the solar module 300 to consolidate into a single mass, which becomes solid either as the assembly cools, or after the polymer material, if a thermosetting type, cross-links at an elevated temperature. Alternatively, the polymer 310 may be introduced to the module assembly 300 in the form of a liquid, which is later caused to solidify through the application of heat or UV radiation.

It will be appreciated that for embodiments of the diffractive optical member 306 which comprise materials that can withstand outdoor exposure, the diffractive optical member 306 can itself be used as the bottom protective covering of a solar module 300, and can be substituted for any other bottom protective covering material during the assembly and lamination process described herein, thereby producing a solar module 300 with the desired properties. Alternately, if the diffractive optical member material is not sufficiently durable to be used as a protective covering itself, it is inserted into the assembly 300 between the solar cells 304 and the bottom protective covering 312, with suitable layers of bonding material 310 between it and the solar cells 304 and the bottom protective covering 312. One method for executing this design is to pre-bond the diffractive optical member 306 to the bottom protective covering material 312 in a process separate from the module assembly itself. The laminate comprising the diffractive optical member 306 bonded to the bottom protective covering material 312 can then be used as the bottom protective covering during conventional module assembly, and confers the benefits of both the rear (back) side protective covering and of the diffractive optical member 306.

In one embodiment, the laminate comprising the diffractive optical member 306 bonded to the bottom protective covering material 312 is a composite backskin 60.

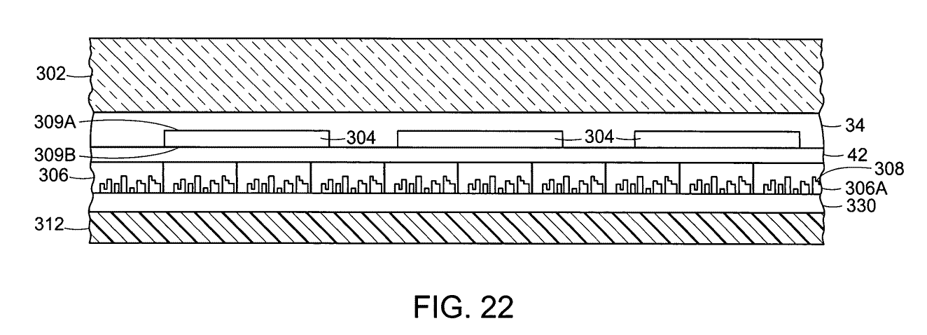

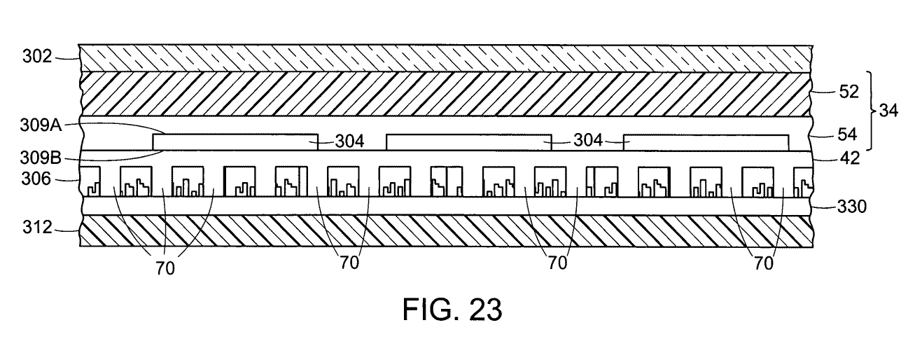

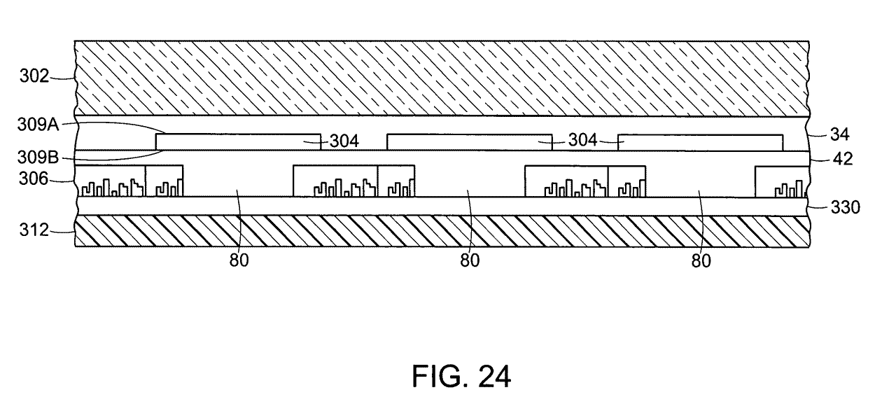

FIG. 22 is a sectional view of a solar module including a diffractive optical member 306 having a substrate 306A and diffractive surface 308, in accordance with the principles of the invention. The solar module includes a first transparent layer 34, a second transparent layer 42, and a back encapsulating layer 330. The back encapsulating layer 330 can be a polymer encapsulant, such as EVA. The diffractive surface 308 shown in FIG. 22 is an exemplary surface and is not meant to be limiting of the invention. FIG. 23 is a sectional view of a solar module including a weight mitigation layer 52 and moisture control perforations 70 in a diffractive optical member 306, in accordance with the principles of the invention. FIG. 24 is a sectional view of a solar module including moisture control windows 80 in a diffractive optical member 306, in accordance with the principles of the invention. The perforations 70 or windows 80 extend through the diffractive optical member 306, including the substrate 306A, the relief pattern surface 308, and the metallic coating layer (disposed onto the relief pattern surface 308). In one embodiment, the metallic coating layer is a coating layer 212 (see FIG. 14). If the diffractive optical member 306 also includes an insulation layer, then the perforations 70 or windows 80 also extend through the insulation layer. In one embodiment, the insulation is a layer overcoating the metallic coating layer.

In one embodiment, the relief pattern surface 308 faces towards the back surfaces 309B of the solar cells 304.

In another embodiment, the relief pattern surface 308 faces away from the back surfaces 309B of the solar cells 304. If the relief pattern surface 308 faces away form the back surfaces 309B, then the diffractive optical member 306 may not require an insulation coating or layer. In one embodiment, if no insulation layer is required, then the perforations 70 or windows 80 extend through the metallic coating layer only.

If the metallic coating layer is sufficiently thin (for example 300 Angstroms or less), then the metallic coating layer provides a measure of moisture permeability and no perforations 70 or windows 80 are required. In this case, the moisture control feature is the thinness of the metallic coating layer. If a thicker metallic coating layer is required, then perforations 70 or windows 80 is required. In another embodiment, the use of a relatively thin metallic coating layer allows the use of fewer perforations 70 or smaller windows 80 than would be required for a thicker metallic coating layer.

The solar module of FIG. 23 illustrates a weight mitigation layer 52. FIG. 23 is not meant to be limiting of the invention, and a weight mitigation layer 52 can be used independently of the moisture control feature (for example, perforations 70). FIG. 24 is not meant to be limiting of the invention, and a weight mitigation layer 52 can be included in FIG. 24 with the moisture control feature (for example, windows 80).

In one embodiment, the diffractive optical member 306 includes a relief pattern surface 308 forming a one-level diffractive structure. The one-level diffractive structure provides a one step relief pattern. In one embodiment, the diffractive structure (for multilevel diffractive structures) is fabricated in a process shown in FIGS. 19A-19H. For an embodiment having a one-level diffractive structure, the fabrication process proceeds as shown, in an exemplary manner, for FIGS. 19A-19D, resulting in a one-level diffractive structure illustrated by repeated one-level steps or plateaus 244 on the substrate 230 as shown in FIG. 19D that are one step in height above a base level (for example, base level indicated by areas 238 not covered by the photoresist). FIGS. 19E-19H indicate that the process proceeds to the fabrication of a multilevel pattern (as shown by the multilevel diffraction structure illustrated in FIG. 19H). For a one-level result, the fabrication process does not proceed to completion with the process as taught in FIGS. 19A-19H.

The one-level diffractive structure is less complex to manufacture, as indicated, for example, by requiring only the process shown in FIGS. 19A-19D. For any diffractive structure, the height of the levels must be controlled precisely, for heights that are, in one embodiment, 2 microns or less in height. The heights of the one-level steps 244 are easier to control because there is a less complex process to construct the one-level steps 244, and only one level of steps is being created in comparison to multiple step structures (see FIGS. 19E-19H). In addition, the manufacturing process requires, in one embodiment, the use and copying of a master pattern of the diffraction relief pattern. The master pattern is copied to a shim, which is typically copied again to produce a plate with a repeated pattern, which is copied again to a larger shim having the repeated pattern (which is used in the actual manufacturing of a diffractive optical member 306). For example, the larger shim is mounted on a drum and used to impress the relief pattern onto a substrate or film 306A. In one embodiment, the substrate or film 306A has a thickness of about 0.005 to about 0.010 inches in thickness. This fabrication process is discussed herein in more detail in relation to FIGS. 19A-19E.

At each step in the relief copying process, there is a risk of some deterioration in the fine detail of the relief pattern, and the risk is less if the relief pattern is a simpler pattern (for example, the one-level pattern). Also, the larger shim, which is used in the manufacturing process repeatedly to emboss the relief pattern on a film, suffers some deterioration over time due to repeated use of the larger shim. This deterioration is likely to be at a higher rate for a multilevel pattern, because of the greater complexity of the multiple step pattern compared to one-level pattern. Thus, the larger shim is likely to require replacement more often with a multilevel pattern than a larger shim having a one-level pattern. The one-level diffractive structure can have an efficiency in redirecting light of as much as 80 percent. Multilevel diffractive structures can have a higher efficiency (as much as 95 percent) but carry the risks of greater complexity and greater manufacturing costs.

In one embodiment, a scrim layer is included in the module, disposed adjacent to the back surface of the solar cell (for example, back surface 309B of the solar cell 304). The scrim layer is a porous layer that assists in the movement of gas bubbles during the module lamination process to help remove the bubbles from the encapsulant. In one embodiment, the scrim layer is a fiberglass material of about 0.010 inch in thickness, or other suitable porous material.

Having described the preferred embodiments of the invention, it will now become apparent to one of skill in the arts that other embodiments incorporating the concepts may be used. It is felt, therefore, that these embodiments should not be limited to the disclosed embodiments but rather should be limited only by the spirit and scope of the following claims.

What is claimed is:

1. A solar electric module comprising:
a transparent front cover having a front surface and a back surface;
a plurality of solar cells configured in a substantially coplanar arrangement and spaced apart from each other;
a back cover spaced apart from and substantially parallel to said transparent front cover, said plurality of solar cells disposed between said transparent front cover and said back cover, said solar cells having front surfaces facing said transparent front cover and back surfaces facing away from said transparent front cover, each solar cell having one front surface and one back surface;
a light transmitting encapsulant disposed between said transparent front cover and said back cover; and
a light redirection layer disposed between said solar cells and said back cover, said transparent front cover transmitting light through said transparent front cover and incident on said light redirection layer in regions between said solar cells, said light redirection layer directing said light towards said transparent front cover, and said front surface of said transparent front cover internally reflecting said light back towards said front surfaces of said solar cells;
said light redirection layer having a plurality of perforations of a predetermined size at least in regions obscured by said solar cells, said perforations providing moisture transport into and out from said light transmitting encapsulant.

2. The solar electric module of claim 1, wherein said light redirection layer is an asymmetric redirection layer providing light redirection in asymmetric directions.

3. The solar electric module of claim 2, said asymmetric redirection layer comprising a light scattering film and a light reflective layer.

4. The solar electric module of claim 3, wherein only said light reflective layer comprises said perforations.

5. The solar electric module of claim 4, said perforations forming a plurality of windows, each window adjacent to each back surface of each solar cell.

6. The solar electric module of claim 3, said light scattering film and said light reflective layer having said perforations, each perforation extending through said light scattering film and said light reflective layer.

7. The solar electric module of claim 6, said perforations forming a plurality of windows, each window extending through said light scattering film and said light reflective layer, each window located adjacent to each solar cell.

8. The solar electric module of claim 1, wherein said light redirection layer is a symmetric redirection layer providing light redirection in symmetric modes.

9. The solar electric module of claim 8, said symmetric redirection layer comprising a diffractive optical member.

10. The solar electric module of claim 9, said perforations forming a plurality of windows, each window adjacent to each back surface of each solar cell.

11. The solar electric module of claim 9, said diffractive optical member comprising a substrate, a surface having a diffractive relief pattern, and a metallic coating layer disposed onto said relief pattern surface.

12. The solar electric module of claim 11, wherein said substrate, said relief pattern surface, and said metallic coating layer have said perforations, each perforation extending through said substrate, said relief pattern surface, and said metallic, coating layer.

13. The solar electric module of claim 11, said diffractive optical member further comprising an insulation layer.

14. The solar electric module of claim 13, wherein said substrate, said relief pattern surface said metallic coating layer, and said insulation layer have said perforations, each perforation extending through said substrate, said relief pattern surface, said metallic coating layer and said insulation layer.

15. The solar electric module of claim 11, said relief pattern surface facing away from said back surface of said solar cells.

16. The solar electric module of claim 11, said relief pattern surface forming a one-level diffractive structure.

17. A solar electric module comprising:
a transparent front cover having a front surface and a back surface;
a plurality of solar cells configured in a substantially coplanar arrangement and spaced apart from each other;
a back cover spaced apart from and substantially parallel to said transparent front cover, said plurality of solar cells disposed between said transparent front cover and said back cover, said solar cells having front surfaces facing said transparent front cover and having back surfaces facing away from said transparent front cover, each solar cell having one front surface and one back surface;
a light transmitting layer disposed between said transparent front cover and said back cover and encapsulating said solar cells, said light transmitting layer comprising a first layer of transparent material disposed adjacent to said back surface of said transparent front cover and a second layer of transparent material disposed adjacent to said back surfaces of said solar cells; and
a light redirection layer disposed between said solar cells and said back cover, said transparent front cover transmitting light through said transparent front cover and incident on said light redirection layer in regions between said solar cells, said light redirection layer directing said light towards said transparent front cover, and said front surface of said transparent front cover internally reflecting said light back towards said front surfaces of said solar cells;
said first layer of transparent material comprising at least one encapsulating sheet adjacent to said front surfaces of said solar cells, and a weight mitigation layer disposed between said back surface of said transparent front cover and said at least one encapsulating sheet; said weight mitigation layer having a density less than said transparent front cover, and replacing a volume of said transparent front cover equal to a volume of said weight mitigation layer.

18. The solar electric module of claim 17, wherein said light redirection layer is an asymmetric redirection layer providing light redirection in asymmetric directions.

19. The solar electric module of claim 18, said asymmetric redirection layer comprising a light scattering film and a light reflective layer.

20. The solar electric module of claim 17, wherein said light redirection layer is a symmetric redirection layer providing light redirection in symmetric modes.

21. The solar electric module of claim 20, said symmetric redirection layer comprising a diffractive optical member.

22. The solar electric module of claim 21, said diffractive optical member comprising a substrate, a surface having a diffractive relief pattern, and a metallic coating layer.

23. The solar electric module of claim 22, said diffractive optical member further comprising an insulation layer.

24. The solar electric module of claim 22, said relief pattern surface facing away from said back surface of said solar cells.

25. The solar electric module of claim 22, said relief pattern surface forming a one-level diffractive structure.

26. A solar electric module comprising:
a transparent front cover having a front surface and a back surface;
a plurality of solar cells configured in a substantially coplanar arrangement and spaced apart from each other;
a back cover spaced apart from and substantially parallel to said transparent front cover, said plurality of solar cells disposed between said transparent front cover and said back cover, said solar cells having front surfaces facing said transparent front cover and back surfaces facing away from said transparent front cover, each solar cell having one front surface and one back surface;
a light transmitting encapsulant disposed between said transparent front cover and said back cover; and
means for light redirection disposed between said solar cells and said back cover, said transparent front cover transmitting light through said transparent front cover and incident on said light redirection means in regions between said solar cells, said light redirection means directing said light towards said transparent front cover, and said front surface of said transparent front cover internally reflecting said light back towards said front surfaces of said solar cells;
said light redirection means having a plurality of perforations of a predetermined size at least in regions obscured by said solar cells, said perforations providing moisture transport into and out from said light transmitting encapsulant.

27. The solar electric module of claim 26, wherein said light redirection means is a means for asymmetric light redirection providing light redirection in asymmetric directions.

28. The solar electric module of claim 26, wherein said light redirection means is a means for symmetric light redirection providing light redirection in symmetric modes.

29. A solar electric module comprising:
a transparent front cover having a front surface and a back surface;
a plurality of solar cells configured in a substantially coplanar arrangement and spaced apart from each other;
a back cover spaced apart from and substantially parallel to said transparent front cover, said plurality of solar cells disposed between said transparent front cover and said back cover, said solar cells having front surfaces facing said transparent front cover and having back surfaces facing away from said transparent front cover, each solar cell having one front surface and one back surface;
a light transmitting layer disposed between said transparent front cover and said back cover and encapsulating said solar cells, said light transmitting layer comprising a first layer of transparent material disposed adjacent to said back surface of said transparent front cover and a second layer of transparent material disposed adjacent to said back surfaces of said solar cells; and
means for light redirection disposed between said solar cells and said back cover, said transparent front cover transmitting light through said transparent front cover and incident on said light redirection means in regions between said solar cells, said light redirection means directing said light towards said transparent front cover, and said front surface of said transparent front cover internally reflecting said light back towards said front surfaces of said solar cells;
said first layer of transparent material comprising at least one encapsulating sheet adjacent to said front surfaces of said solar cells, and a weight mitigation layer disposed between said back surface of said transparent front cover and said at least one encapsulating sheet; said weight mitigation layer having a density less than said transparent front cover, and replacing a volume of said transparent front cover equal to a volume of said weight mitigation layer.

30. The solar electric module of claim 29, wherein said light redirection means is a means for asymmetric light redirection providing light redirection in asymmetric directions.

31. The solar electric module of claim 29, wherein said light redirection means is a means for symmetric light redirection providing light redirection in symmetric modes.
